(19) United States
(12) Patent Application Publication
(10) Pub. No.: US 2025/0246520 A1
(43) Pub. Date: Jul. 31, 2025

(54) INTEGRATED CIRCUIT PACKAGE WITH PACKAGE RESISTOR

(71) Applicant: TEXAS INSTRUMENTS INCORPORATED, Dallas, TX (US)

(72) Inventors: Ankit KHANNA, Tucson, AZ (US); Dimitar TRIFONOV, Vail, AZ (US); Ravinthiran BALASINGAM, Tucson, AZ (US); Vamsi Krishna YELLA, Tucson, AZ (US)

(21) Appl. No.: 18/758,172

(22) Filed: Jun. 28, 2024

Related U.S. Application Data
(60) Provisional application No. 63/626,217, filed on Jan. 29, 2024.

(51) Int. Cl. H01L 23/495; H01L 23/00; H01L 23/31; H03F 3/04; H03G 3/30

(52) U.S. Cl. CPC H01L 23/49541; H01L 24/48; H01L 24/49; H03F 3/04; H03G 3/30; H01L 23/3107; H01L 2224/48249; H01L 2224/4912; H03G 2201/103

(57) ABSTRACT

An integrated circuit (IC) package includes: a package resistor having a first terminal and second terminal; and an IC separate from and coupled to the package resistor. The IC includes sense circuitry having a first terminal and a second terminal. The first terminal of the sense circuitry is coupled to the first terminal of the package resistor. The second terminal of the sense circuitry is coupled to the second terminal of the package resistor.

### CROSS-REFERENCE TO RELATED APPLICATIONS

The present application claims priority to U.S. Provisional Application No. 63/626,217, titled “ANALOG OUTPUT CURRENT SENSOR WITH INTEGRATED SHUNT RESISTOR AND DYNAMIC TEMPERATURE DRIVER CORRECTION”, Attorney Docket number T104079US01, filed on Jan. 29, 2024, which is hereby incorporated by reference in its entirety.

### BACKGROUND

Many sense circuits for sensing current or voltage for instance, are subject to aging, stress-induced error, or system limitations. Accordingly, an initial design or calibration for such sense circuits eventually produces less accurate results and may even fall out of a target tolerance. An example sense circuit may include a sense resistor and an integrated circuit (IC) with a sense amplifier. When the IC and sense resistor are mounted to a printed circuit board (PCB), the PCB traces between the sense resistor and the IC may cause additional error or limitations.

### SUMMARY

In an example, an integrated circuit (IC) package includes: a package resistor having a first terminal and second terminal; and an IC separate from and coupled to the package resistor. The IC includes sense circuitry having a first terminal and a second terminal. The first terminal of the sense circuitry is coupled to the first terminal of the package resistor. The second terminal of the sense circuitry is coupled to the second terminal of the package resistor.

In another example, an IC package includes: a leadframe including an integrated leadframe resistor having a first terminal and a second terminal; and an IC on the leadframe resistor. The IC has a first terminal coupled to the first terminal of the leadframe resistor and a second terminal coupled to the second terminal of the leadframe resistor. In yet another example, an IC package includes a package resistor having first and second terminals; and an IC. The IC includes: an amplifier; and a calibration controller. The amplifier has a first terminal coupled to the first terminal of the package resistor and a second terminal coupled to the second terminal of the package resistor. The amplifier includes adjustable circuitry configured to adjust a gain of the amplifier. The adjustable circuitry has an input. The calibration controller includes gain control circuitry having an output coupled to the input of the adjustable circuitry, the gain control circuitry configured to provide a calibration setting, at the output, responsive to a digital temperature code.

### BRIEF DESCRIPTION OF THE DRAWINGS

FIG. 1 is a diagram showing an example system.

FIG. 2 is a diagram showing another example system.

FIG. 3 is a top view of a printed circuit board with an example integrated circuit (IC) package.

FIG. 4A is a perspective top side view of an example IC package.

FIG. 4B is a perspective bottom side view of the example IC package of FIG. 4A.

FIG. 5A is a first cross-sectional view of the example IC package of FIGS. 4A and 4B.

FIG. 5B is a second cross-sectional view of the example IC package of FIGS. 4A and 4B.

FIG. 5C is a first cross-sectional view of another example IC package.

FIG. 5D is a second cross-sectional view of the example IC package of FIG. 5C.

FIG. 6A is a bottom-side view of the example IC package of FIGS. 4A and 4B.

FIG. 6B is an internal view of the example IC package of FIGS. 4A and 4B.

FIG. 6C is an interior view of another example IC package.

FIG. 6D is an interior view of another example IC package.

FIG. 7A is an example graph of resistance as a function of temperature for an example leadframe resistor.

FIG. 7B is an example graph of system gain as a function of temperature for example sense circuitry.

FIG. 7C is an example graph of system gain as a function of temperature for other example sense circuitry.

FIG. 8 is a diagram of an example IC package.

FIG. 9 is a diagram of an example sense circuit calibration technique.

FIG. 10 is a diagram of another example IC package.

### DETAILED DESCRIPTION

The same reference numbers or other reference designators are used in the drawings to designate the same or similar features. Such features may be the same or similar either by function and/or structure.

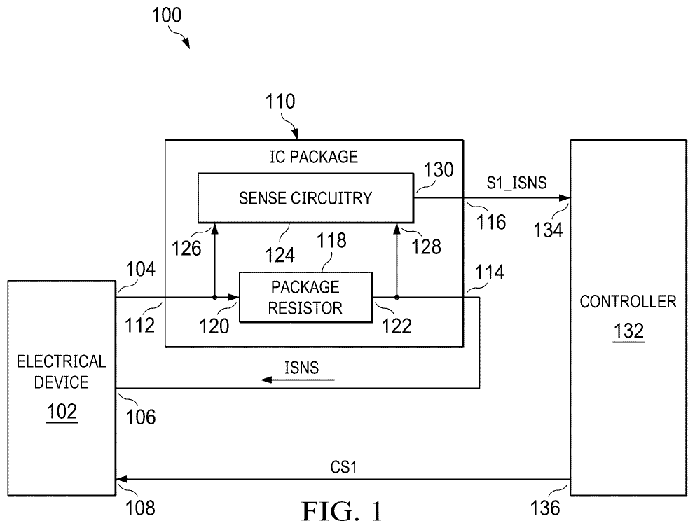

FIG. 1 is a diagram showing an example system 100. In different examples, the system 100 is part of an overcurrent protection system, a battery management system, a power telemetry system, a motor or solenoid control system, or other system. As shown, the system 100 includes an electrical device 102, an integrated circuit (IC) package 110, and a controller 132. In different examples, the electrical device 102 may be a battery, a motor, a solenoid, a telemetry device, a power regulation device, or other electrical device. In the example of FIG. 1, the electrical device 102 has a first terminal 104, a second terminal 106, and third terminal 108. The IC package 110 has a first terminal 112, a second terminal 114, and a third terminal 116. The controller 132 has a first terminal 134 and a second terminal 136.

In the example of FIG. 1, the IC package 110 includes a package resistor 118 and sense circuitry 124. The package resistor 118 has a first terminal 120 and a second terminal 122. The sense circuitry 124 has a first terminal 126, a second terminal 128, and a third terminal 130. In some examples, the sense circuitry 124 is part of an IC. In some examples, the package resistor 118 is a leadframe resistor separate from the IC.

As used herein, a “leadframe” refers to a support and connectivity structure for an IC. For example, the support and connectivity structure may include a support platform for the IC, bondpads for connection to respective bondpads of an IC, and an external terminal for each respective bondpad. The external terminals are used to couple the bondpads of the leadframe and respective bondpads of the IC to external circuitry. In other examples, a leadframe omits at least some bondpads such that bondpads of an IC are coupled directly to external terminals via bondwires. As another option, a leadframe may include some bondpads for some external terminals but not all external terminals. IC bondpads or leadframe bondpads are sometimes referred to as “internal terminals” or just “terminals” herein.

As used herein, a “leadframe resistor” refers to a resistive material that is part of or is integrated with the leadframe. In some examples, a leadframe resistor is the resistance between at least two spaced connection points or bondpads of the leadframe. The resistive material may be integrated with the support platform of the leadframe or may be separate from the support platform and/or from the external terminals of the leadframe.

As used herein, a “package resistor” is either a leadframe resistor, an on-chip resistor, or an off-chip resistor embedded within the encapsulant material of the IC package 110 and separate from the IC and the leadframe. In different examples, the materials, dimensions, and position of an off-chip resistor vary. As needed, the total volume of encapsulant for an IC package may be adjusted to account for an off-chip resistor.

In the example of FIG. 1, the first terminal 104 of the electrical device 102 is coupled to the first terminal 112 of the IC package 110. The second terminal 106 of the electrical device 102 is coupled to the second terminal 114 of the IC package 110. The third terminal 116 of the IC package 110 is coupled to the first terminal 134 of the controller 132. The second terminal 136 of the controller 132 is coupled to the third terminal 108 of the electrical device 102.

The first terminal 112 of the IC package 110 is coupled to the first terminal 120 of the package resistor 118 and the first terminal 126 of the sense circuitry 124. The second terminal 114 of the IC package 110 is coupled to the second terminal 122 of the package resistor 118 and the second terminal 128 of the sense circuitry 124. The third terminal 130 of the sense circuitry 124 is coupled to the third terminal 116 of the IC package 110.

In some examples, the electrical device 102 operates to: receive a control signal CS1 at the third terminal 108; and perform an operation responsive to the control signal CS1. During operations of the electrical device 102, a current ISNS flows from the first terminal 104 and through the package resistor 118. In the example of FIG. 1, the current ISNS flows back to the second terminal 106 of the electrical device 102. In other examples, the current ISNS flows to a ground terminal. In either case, the current ISNS is monitored by the sense circuitry 124. In some examples, the sense circuitry 124 monitors the current ISNS by monitoring a voltage drop across the package resistor 118. In such examples, the sense circuitry 124 operates to: receive a first voltage level at the first terminal 126; receive a second voltage level at the second terminal 128; and provide a current sense signal S1_ISNS at the third terminal 130 responsive to the first voltage level and the second voltage level. The controller 132 operates to: receive the sense signal S1_ISNS at the first terminal 134; and adjust the control signal CS1 responsive to the current sense signal S1_ISNS. In some examples, the process of monitoring the current ISNS using package resistor 118 and the sense circuitry 124, providing the current sense signal S1_ISNS to the controller 132, and adjusting the control signal CS1 for the electrical device 102 is repeated to provide ongoing overcurrent protection, ongoing battery management, ongoing power telemetry, ongoing motor control, ongoing solenoid control, ongoing power regulation, or other system operations.

With the IC package 110 and package resistor 118, an external sense resistor is avoided, which in some applications leads to resistor selection, procurement and printed circuit board (PCB) layout issues. In some examples, the sense circuitry 124 may include an adjustable component (also referred to as adjustable circuitry) and a calibration controller, where calibration operations account for error resulting from the package resistor 118. Such error may be due to resistor value drift of the package resistor 118 as a function of temperature.

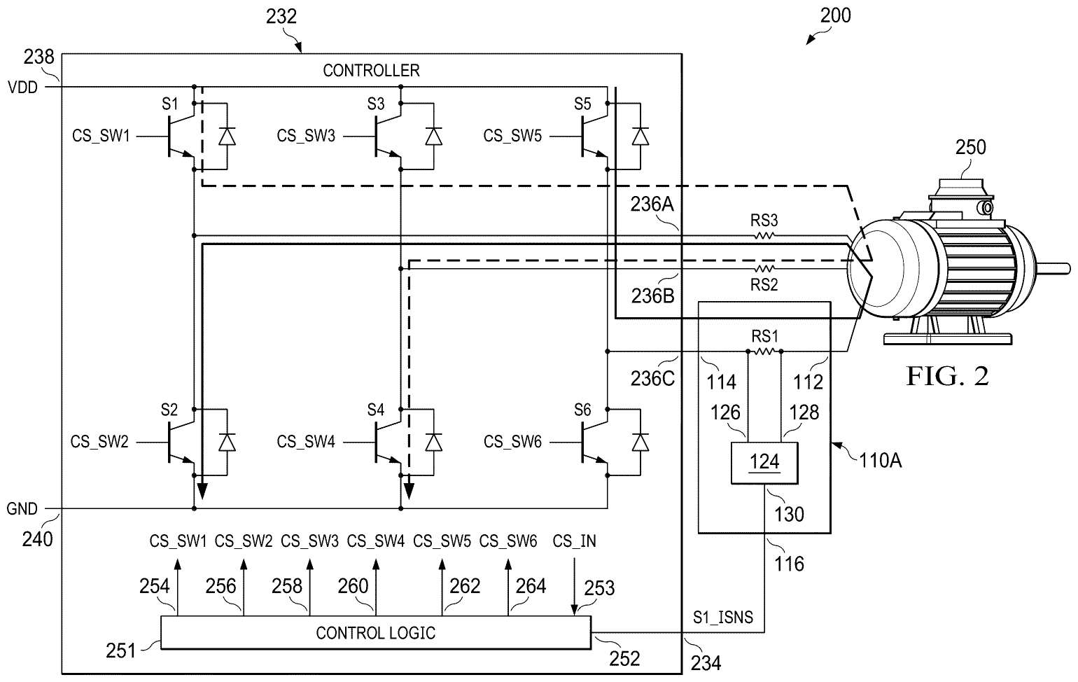

FIG. 2 is a diagram showing another example system 200. In the example of FIG. 2, the system 200 includes a motor 250, an IC package 110A, and a controller 232. The motor 250 is an example of the electrical device 102 in FIG. 1. In some examples, motor 250 is a 3-phase motor. The IC package 110A is an example of the IC package 110 in FIG. 1. The controller 232 is an example of the controller 132 in FIG. 1.

In the example of FIG. 2, the IC package 110A has the first terminal 112, the second terminal 114, and the third terminal 116 described in FIG. 1. As shown, the IC package 110A includes a resistor RS1 and the sense circuitry 124. The resistor RS1 is an example of the package resistor 118 in FIG. 1.

In the example of FIG. 2, the controller 232 has a first terminal 234, second terminals 236A to 236C, a third terminal 238, and a fourth terminal 240. The first terminal 234 is an example of the first terminal 134 in FIG. 1. The second terminals 236A to 236C are respective examples of the second terminal 136 in FIG. 1. The third terminal 238 is a power supply terminal that may be included with the controller 132 in FIG. 1. The fourth terminal 240 is a ground terminal that may be included with the controller 132 in FIG. 1.

In the example of FIG. 2, the controller 232 includes switches S1 to S6 and control logic 251. Each of the switches S1 to S6 has a respective first terminal, a respective second terminal, and a respective control terminal. The control logic 251 has a first terminal 252, a second terminal 253, a third terminal 254, a fourth terminal 256, a fifth terminal 258, a sixth terminal 260, a seventh terminal 262, and an eighth terminal 264. The first terminal 252 of the control logic 251 is coupled to the first terminal 234 of the controller 232. The second terminal 253 of the control logic 251 receives control signals CS_IN. In some examples, the control signals CS_IN may include motor speed, direction of rotation, motor position, and/or other control parameters. The third terminal 254 of the control logic 251 is coupled to the control terminal of the switch S1. The fourth terminal 256 of the control logic 251 is coupled to the control terminal of the switch S2. The fifth terminal 258 of the control logic 251 is coupled to the control terminal of the switch S3. The sixth terminal 260 of the control logic 251 is coupled to the control terminal of the switch S4. The seventh terminal 262 of the control logic 251 is coupled to the control terminal of the switch S5. The eighth terminal 264 of the control logic 251 is coupled to the control terminal of the switch S6.

In the example of FIG. 2, the first terminals of the switches S1, S3, and S5 are coupled to the third terminal 238 of the controller 232. The second terminal of the switch S1 is coupled to the first terminal of the switch S2 and the second terminal 236A of the controller 232. The second terminal of the switch S3 is coupled to the first terminal of the switch S4 and the second terminal 236B of the controller 232. The second terminal of the switch S5 is coupled to the first terminal of the switch S6 and the second terminal 236C of the controller 232. The second terminals of the switches S2, S4, and S6 are coupled to the fourth terminal 240 of the controller 232.

In the example of FIG. 2, the controller 232 operates to: receive a power supply voltage (VDD) at the third terminal 238; receive the current sense signal S1_ISNS; and provide current to the second terminals 236A to 236C responsive to the VDD, S1_ISNS, CS_IN, and the operations of the control logic 251. In some examples, the control logic 251 operates to: receive S1_ISNS at the first terminal 252; receive CS_IN at the second terminal 253; and provide switch control signals CS_S1, CS_S2, CS_S3, CS_S4, CS_S5, and CS_S6 at the third terminal 254, fourth terminal 256, fifth terminal 258, sixth terminal 260, seventh terminal 262, and the eighth terminal 264 responsive to the S1_ISNS and CS_IN. In some examples, the control logic 251 operates to: send a pulse-wide modulation (PWM) signal to the switches S1 to S6 to control their on/off state in a sequential manner which results in rotation of the motor 250. In some examples, the control logic 251 operates to: monitor S1_ISNS and other sensor inputs; and alter the frequency and/or the duty cycle of the PWM signal to the switches S1 to S6 to regulate motion of the motor 250.

In the example of FIG. 2, one IC package 110A provides the current sense signal S1_ISNS for the current through RS1 and the second terminal 236C. In some examples, there may be a second IC package to provide a second current sense signal S2_ISNS (not shown) for the current through RS2 and the second terminal 236B. Also, there may be a third IC package to provide a third current sense signal S3_ISNS (not shown) for the current through RS3 and the second terminal 236A. In such examples, the controller 232 and the control logic 251 may include additional terminals to receive the second current sense signal S2_ISNS and the third current sense signal S3_ISNS. In such examples, the control logic 251 may operate to: receive S1_ISNS at the first terminal 252; receive S2_ISNS; receive S3_ISNS; and provide switch control signals CS_S1, CS_S2, CS_S3, CS_S4, CS_S5, and CS_S6 at the third terminal 254, fourth terminal 256, fifth terminal 258, sixth terminal 260, seventh terminal 262, and the eighth terminal 264 responsive to the S1_ISNS, S2_ISNS, S3_ISNS, and CS_IN.

With the IC package 110A and the resistor RS1, an external sense resistor is avoided, which facilitates resistor selection, procurement, and PCB layout issues. In some examples, the sense circuitry 124 of the IC package 110A may include an adjustable component and a calibration controller, where calibration operations account for error resulting from the package resistor 118. Such error may be due to resistor value drift of the package resistor 118 due to temperature and/or aging.

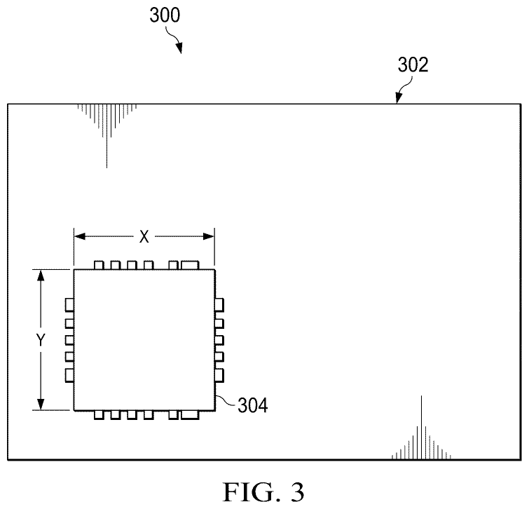

FIG. 3 is a top view 300 of a PCB 302 with an example IC package 304. The IC package 304 is an example of the IC package 110 in FIG. 1 or the IC package 110A in FIG. 2. In the example of FIG. 3, the IC package 304 has a length X and a width Y. In different examples, the dimensions of the IC package 304 may vary. With the IC package 304, an external sense resistor, e.g., on the PCB 302 is avoided, which reduces the layout dimensions of sensing circuitry on the PCB 302. Use of the IC package 304 may also provide benefits such as eliminating resistor selection, simplifying PCB trace layout, and reducing sensing error due to the length of traces between the resistor and the sense circuitry. With a package resistor (e.g., the package resistor 118 in FIG. 1, or the resistor RS1 in FIG. 2), the current sense circuitry (e.g., the sense circuitry 124 in FIGS. 1 and 2) of the IC package 304 may include an adjustable component and a calibration controller, where calibration operations account for error resulting due to the package resistor. Such error may be due to resistor value drift of the package resistor due to temperature.

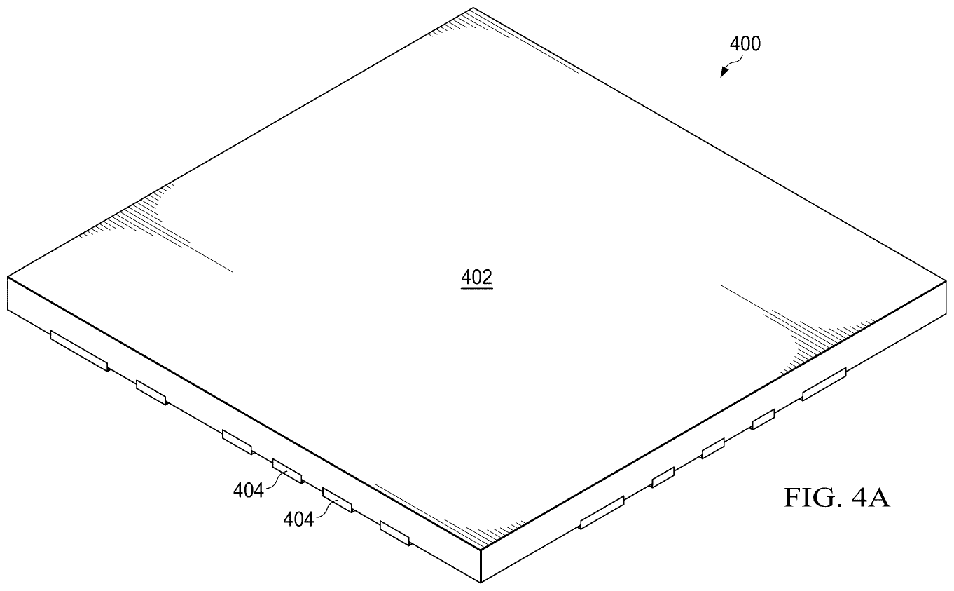

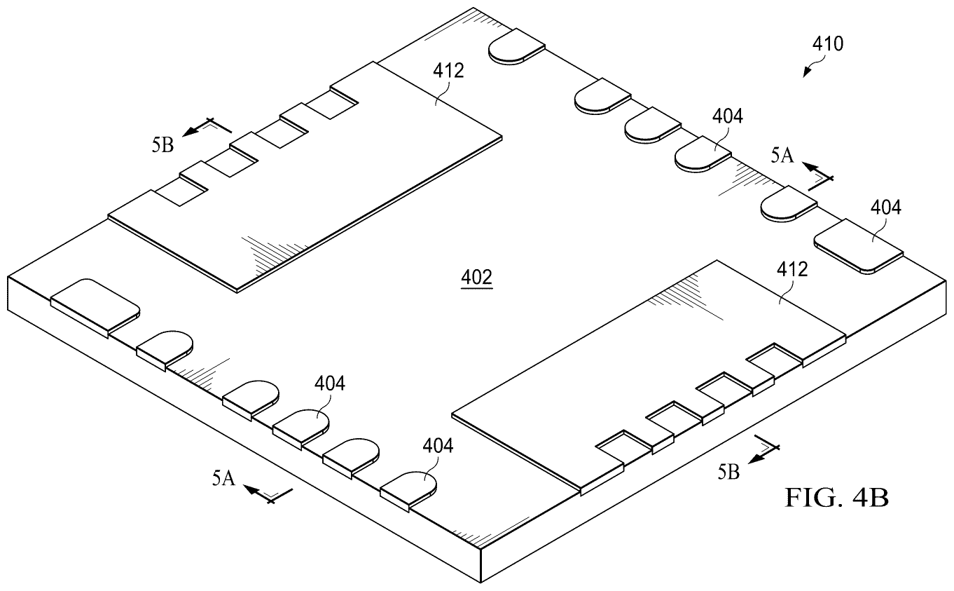

FIG. 4A is a perspective top side view 400 of an example IC package 402. The IC package 402 is an example of the IC package 110 in FIG. 1, the IC package 110A in FIG. 2, or the IC package 304 in FIG. 3. In the example of FIG. 4A, various terminals 404 of the IC package 402 are shown.

FIG. 4B is a perspective bottom side view 410 of the example IC package 402 of FIG. 4A. In the perspective bottom side view 410, more of the terminals 404 are shown. Also, exposed portions of a leadframe 412 are shown. In different examples, the number of terminals 404, the dimensions of the leadframe 412, and the amount of the leadframe 412 that is exposed may vary.

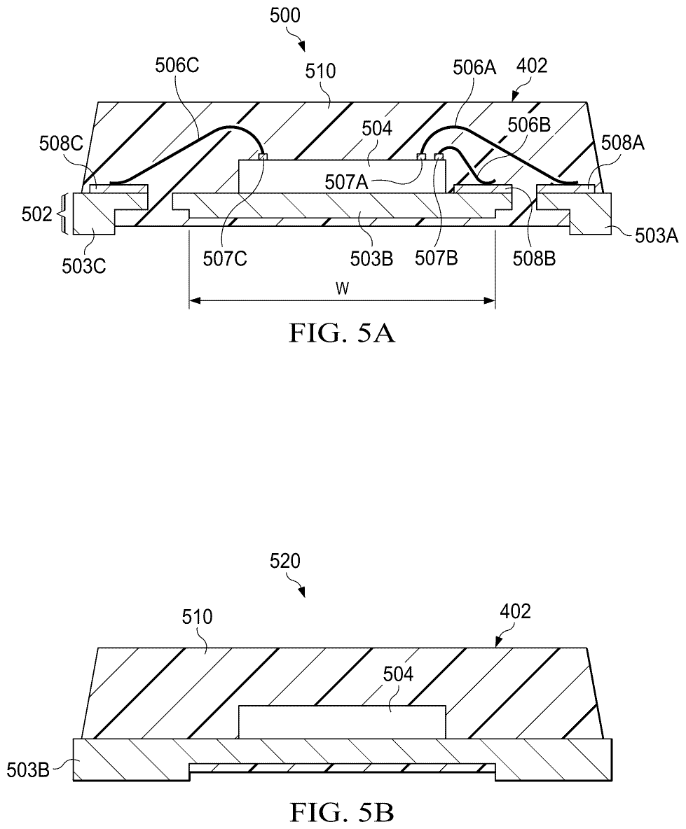

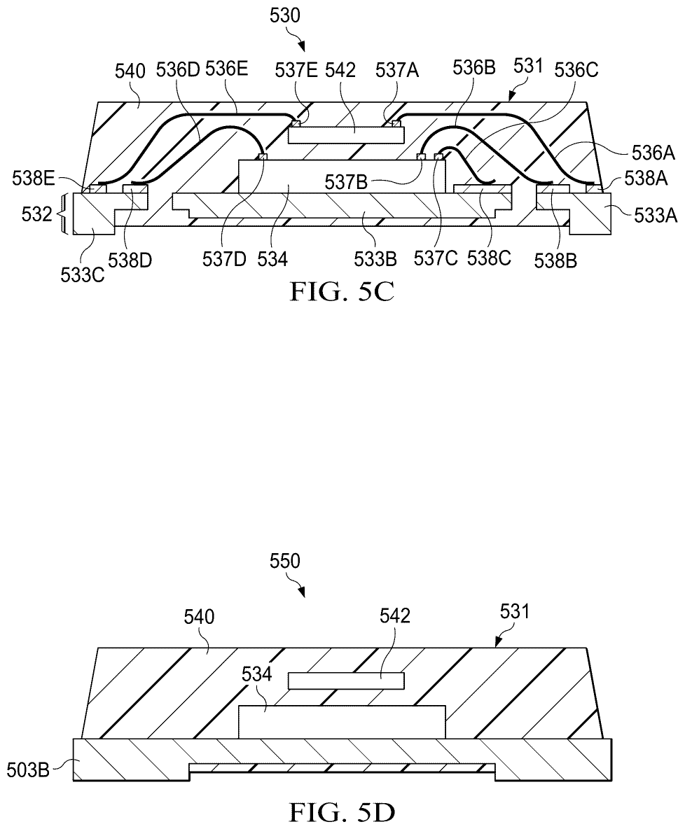

FIG. 5A is a first cross-sectional view 500 of the example IC package 402 of FIGS. 4A and 4B. In the first cross-sectional view 500, a leadframe layer 502, an IC 504, bondpads 508A to 508C, bondwires 506A to 506C, and an encapsulant 510 of the IC package 402 are visible. The leadframe layer 502 includes a first leadframe portion 503A, a second leadframe portion 503B, and a third leadframe portion 503C. The first leadframe portion 503A has bondpads, including the bondpad 508A, and is separated from the second leadframe portion 503B in the first cross-sectional view 500. The second leadframe portion 503B also includes bondpads, including the bondpad 508B. The third leadframe portion 503C also includes bondpads, including the bondpad 508C, and is separated from the second leadframe portion 503B in the first cross-sectional view 500. As shown, the IC 504 has bondpads 507A, 507B, and 507C. The bondpad 507A of the IC 504 is coupled to the bondpad 508A of the first leadframe portion 503A by a respective bondwire 506A. The bondpad 507B of the IC 504 is coupled to the bondpad 508B of the second leadframe portion 503B by a respective bondwire 506A. The bondpad 507C of the IC 504 is coupled to the bondpad 508C of the third leadframe portion 503C by a respective bondwire 506C.

In different examples, the number and arrangement of bondpads of the leadframe layer 502 may vary. Regardless of the number and arrangement of bondpads of the leadframe layer 502, the encapsulant 510 is used to cover bondpads of the leadframe layer 502, bondpads (not shown) of the IC 504, and bondwires coupling bondpads of the leadframe layer 502 and respective bondpads of the IC 504. In the example of FIG. 5A, the second leadframe portion 503B may provide a support platform for the IC 504 as well as a leadframe resistor. In different examples, the width W of the second leadframe portion 503B may vary, which changes the current density and/or resistivity of the related leadframe resistor.

FIG. 5B is a second cross-sectional view 520 of the example IC package 402 of FIGS. 4A and 4B. In the second cross-sectional view 520, the second leadframe portion 503B, the IC 504, and the encapsulant 510 of the IC package 402 are visible. In the example of FIGS. 5A and 5B, the second leadframe portion 503B or part of the second leadframe portion 503B is used as a leadframe resistor and a support platform for the IC 504.

FIG. 5C is a first cross-sectional view 530 of another example IC package 531. The IC package 531 of FIGS. 5C and 5D differs from the IC package 402 of FIG. 4B or the IC package 510 of FIGS. 5A and 5B due to use of an off-chip resistor 542 instead of a leadframe resistor. In the first cross-sectional view 530, a leadframe layer 532, an IC 534, bondpads 538A to 538E, bondwires 536A to 536E, an off-chip resistor 542, and an encapsulant 540 of the IC package 531 are visible. The leadframe layer 532 includes a first leadframe portion 533A, a second leadframe portion 533B, and a third leadframe portion 533C. The first leadframe portion 533A has bondpads, including the bondpads 538A and 538B, and is separated from the second leadframe portion 533B in the first cross-sectional view 530. The second leadframe portion 533B also includes bondpads, including the bondpad 538C. The third leadframe portion 533C also includes bondpads, including the bondpads 538D and 538E, and is separated from the second leadframe portion 533B in the first cross-sectional view 530.

As shown, the IC 534 has bondpads 537B, 537C, and 537D. The bondpad 537B of the IC 534 is coupled to the bondpad 538B of the first leadframe portion 533A via a respective bondwire 536A. The bondpad 537C of the IC 534 is coupled to the bondpad 538C of the second leadframe portion 533B via a respective bondwire 536C. The bondpad 537D of the IC 534 is coupled to the bondpad 538D of the third leadframe portion 533C via a respective bondwire 536D. In different examples, the number and arrangement of bondpads of the leadframe layer 532 may vary. Regardless of the number and arrangement of bondpads of the leadframe layer 532, some of the encapsulant 540 is used to cover bondpads of the leadframe layer 532, bondpads (not shown) of the IC 534, and bondwires coupling bondpads of the leadframe layer 532 and respective bondpads of the IC 534.

In the example of FIG. 5C, the second leadframe portion 533B may provide a support platform for the IC 534 but does not provide a leadframe resistor. Instead, the off-chip resistor 542 is included. In the example of FIG. 5C, the off-chip resistor 542 is suspended in the encapsulant 540 and has: a first terminal 537A coupled to the bondpad 538A of the leadframe layer 532 using bondwire 536A; and a second terminal 537E coupled to the bondpad 538E of the leadframe layer 532 using bondwire 536E.

In some examples, the off-chip resistor 542 may be put in place after some of the encapsulant 540 covers the IC 534, the bondpads 538B, 538C, and 538D, and respective bondwires 536B, 536C, and 536D and is at least partially cured. The off-chip resistor 542 and bondwires 536A and 536E may then be added and more of the encapsulant 540 is added to cover the off-chip resistor 542, the bondpads 538A and 538E, and the bondwires 536A and 536E.

FIG. 5D is a second cross-sectional view 550 of the example IC package 531 of FIG. 5C. In the second cross-sectional view 550, the second leadframe portion 533B, the IC 534, the off-chip resistor 542, and the encapsulant 540 of the IC package 531 are visible. In the example of FIGS. 5C and 5D, the second leadframe portion 503B is used as a support platform for the IC 534, and the off-chip resistor 542 is used as a package resistor for current sense operations or other operations of the IC 534.

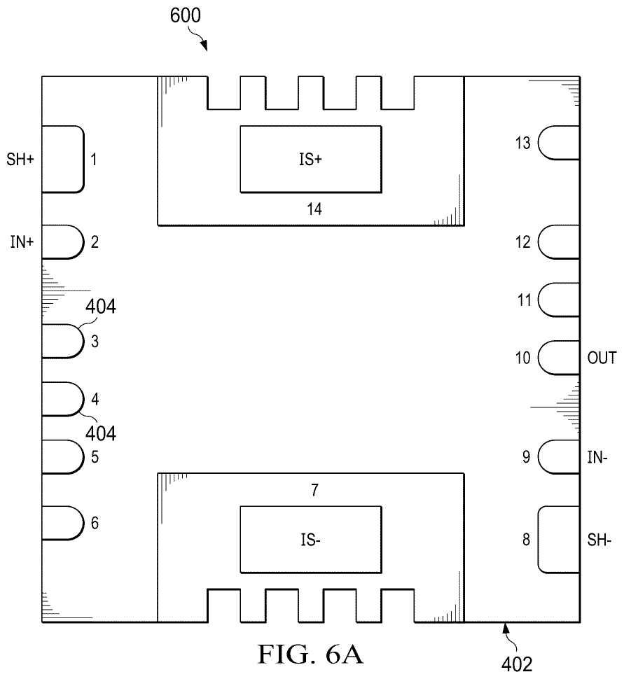

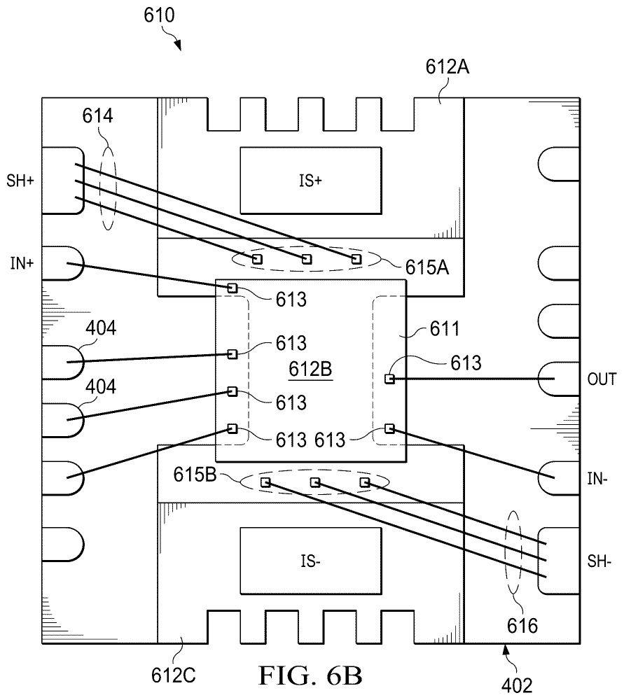

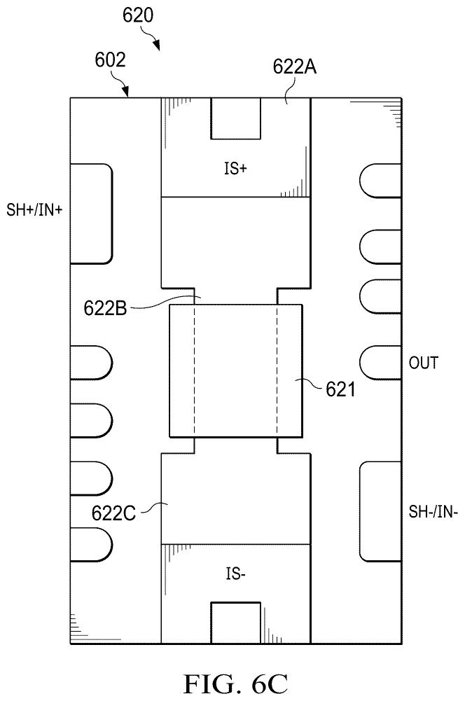

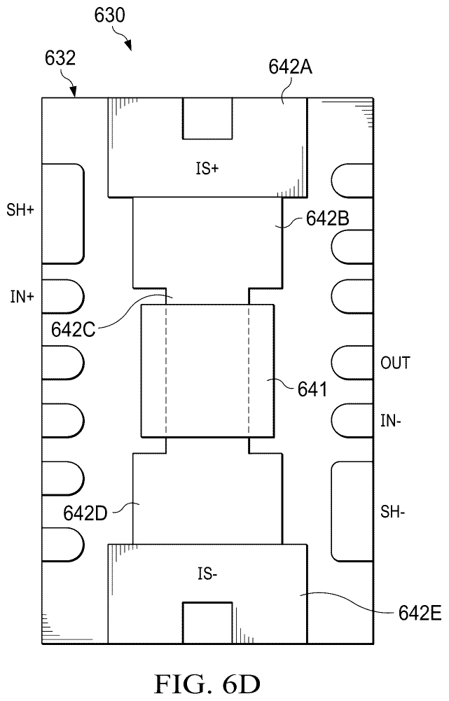

FIG. 6A is a bottom-side view 600 of the example IC package 402 of FIGS. 4A and 4B. As shown, the IC package 402 includes various external terminals 404 labeled terminals 1 to 14. Terminal 1 is an SH+ terminal. Terminal 2 is an IN+ terminal. Terminal 7 is an IS− terminal. Terminal 8 is an SH− terminal. Terminal 9 is an IN− terminal. Terminal 10 is an output (OUT) terminal. Terminal 14 is an IS+ terminal. In different examples, the terminals 3 to 6 and the terminals 11 to 13 may have different functions or no function. Also, in different examples, the function of each of the terminals 1 to 13 may vary.

FIG. 6B is an interior view 610 of the example IC package 402 of FIGS. 4A and 4B. In FIG. 6B, an IC 611 and the external terminals 404 described in FIG. 6A are shown. The IC 611 is an example of an IC related to the sense circuitry 124 in FIGS. 1 and 2, or the IC 504 in FIGS. 5A and 5B. As shown, the SH+ terminal is coupled to the IS+ terminal at terminal or area 615A of the leadframe via first bondwires 614. The SH− terminal is coupled to the IS− terminal at terminal or area 615B of the leadframe via second bondwires 616. Other external terminals 404 of the IC package 402 are coupled to respective bondpads 613 of the IC 611 via respective bondwires (shown but not individually labeled). In other examples, a leadframe (e.g., including the first leadframe subportion 612A, the second leadframe subportion 612B, and third leadframe subportion 612C) may include bondpads, external terminals, and conductive traces between the bondpads and the external terminals. In such examples, bondwires may be coupled between bondpads of the IC and the bondpads of the leadframe. As another option, some bondwires may couple bondpads of an IC directly to external terminals of a leadframe, while other bondwires may couple bondpads of an IC to bondpads of a leadframe (the bondpads of the leadframe being coupled to respective external terminals via conductive traces). In the example of FIG. 6B, the first bondwires 614 includes three bondwires, and the second bondwires 616 includes three bondwires In other examples, the first bondwires 614 and/or the second bondwires 616 may include more or less bondwires. The IN+ terminal, the IN− terminal, and the OUT terminal are coupled to respective bondpads 613 of the IC 611.

In the example of FIG. 6B, the IS+ terminal and the IS− terminal are coupled to a leadframe resistor. In the example of FIG. 6B, the leadframe includes a first leadframe subportion 612A, a second leadframe subportion 612B, and a third leadframe subportion 612C. In the example of FIG. 6B, the first leadframe subportion 612A, the second leadframe portion sub 612B, and the third leadframe subportion 612C may be part of the second leadframe portion 503B in FIGS. 5A and 5B. The first leadframe subportion 612A includes the IS+ terminal. The third leadframe subportion 612C includes the IS− terminal. The second leadframe subportion 612B forms a leadframe resistor between the first leadframe subportion 612A and the third leadframe subportion 612C. In the example of FIG. 6B, the second leadframe subportion 612B is shown using dashed lined to represent the second leadframe subportion 612B being under the IC 611. In some examples, the second leadframe subportion 612B is narrower than the first leadframe subportion 612A and the third leadframe subportion 612C and may provide support for the IC 611. In some examples, the leadframe resistor is integrated with at least the second leadframe subportion 612B and includes resistive material between where the first bondwires 614 and the second bondwires 616 make contact with the leadframe. In the example of FIG. 6B, the leadframe resistor includes the second leadframe subportion 612B, some of first leadframe subportion 612A (where the first bondwires 614 couple to the leadframe), and some of the third leadframe subportion 612C (where the second bondwires 616 couple to the leadframe). In other words, the first bondwires 614 and second bondwires 616 establish voltage sense points that determine where the voltage differential across the leadframe is sensed.

As current passes through the leadframe resistor of the IC package 402, a voltage is developed across it. The first bondwires 614 connect sense points on the leadframe to the SH+ terminal. The second bondwires 616 connect sense points on the leadframe to the SH− terminal. In the example of FIG. 6B, the SH+ terminal is coupled to the IN+ terminal externally (e.g., via a first trace of the PCB) and the SH− terminal is coupled to the IN− terminal externally (e.g., via a second trace of the PCB) to provide the voltages across the leadframe resistor to a PCB. Bondwires connect the IN+ and IN− pins to respective bondpads of the IC 611, thereby enabling current sense circuitry of the IC 611 to sense the voltage developed across the leadframe resistor. In other examples, the first bondwires 614 and second bondwires 616 may couple the leadframe to the IN+/IN− terminals directly (rather than couple the leadframe to the SH+/SH− terminals, couple the SH+ terminal to IN+, and couple the SH− terminal to the IN− terminal). As another option, the IC die may be coupled directly to a leadframe. As another option, the package resistor may be an on-chip resistor. In such examples, the on-chip resistor may carry current densities above a target threshold.

In some examples, the current sense circuitry of the IC 611 include a current sense amplifier that operates to: amplify the voltage differential; and output the amplified result to the OUT terminal as an output voltage VOUT. Assuming the gain of the current sense amplifier is Gain_{Amp} (V/V), the gain of the current sense circuitry may be Gain_{CS}=Rₛₕᵤₙₜ*Gainₐₘₚ (V/A). For example, if the package resistor has a value of 0.4 mOhm and the Gain of the current sense amplifier is 50 V/V, then the gain of the current sense circuitry is 20 mV/A (0.4 m×50). In this example, if a current of 10 A passes through the leadframe, the voltage developed across is 4 mV (0.4 m×10). The current sense amplifier senses this voltage and amplifies it with a gain of 50 V/V to give 0.2V (0.4 m×50 V/V) for the output voltage VOUT. As another option, the output can be calculated by multiplying the input current with the current sensor system gain (e.g., 10 A×20 mV/A=0.2V). In some examples, a REF terminal may be used to add an offset VREF to the output voltage VOUT, which enables measurement of positive and negative currents. In such examples, the gain of the current sense circuitry is VOUT=Rₛₕᵤₙₜ*Gain_{CS}+VREF. As an example, if the current is-10A and VREF is set at 2V, then Vout=−10 A*20 mV/A+2V=1.8V.

FIG. 6C is an interior view 620 of another example IC package 602. The IC package 602 is an example of the IC package 110 in FIG. 1, the IC package 110A in FIG. 2, or the IC package 304 in FIG. 3. In the example of FIG. 6C, the IC package 602 includes an IC 621 and a leadframe, the leadframe including a first leadframe subportion 622A, a second leadframe subportion 622B, and a third leadframe subportion 622C. In the example of FIG. 6C, the first leadframe subportion 622A, the second leadframe subportion 622B, and the third leadframe subportion 622C may be part of the second leadframe portion 503B in FIGS. 5A and 5B. Compared to the IC package 402, the IC package 602 has the same terminals, except the SH+ and IN+ terminals are combined, and the SH− and IN− terminals are combined for the IC package 602. Combining the SH+ and IN+ terminals and combining the SH− and IN− terminals as in the example of FIG. 6C reduces package cost and simplifies the PCB layout. The first leadframe subportion 622A includes the IS+ terminal. The third leadframe subportion 622C includes the IS− terminal. The second leadframe subportion 622B forms a leadframe resistor between the first leadframe subportion 622A and the third leadframe subportion 622C.

In the example of FIG. 6B, part of the second leadframe subportion 622B is shown using dashed lined to represent some of the second leadframe subportion 622B being under the IC 621. In some examples, the second leadframe subportion 622B is narrower than the first leadframe subportion 622A and the third leadframe subportion 622C and may provide support for the IC 621. Comparing the leadframe of FIG. 6C to the leadframe of FIG. 6B, the first leadframe subportion 622A is elongated compared to the first leadframe subportion 612A, the second leadframe subportion 622B is elongated compared to the second leadframe subportion 612B, and the third leadframe subportion 622C is elongated compared to the third leadframe subportion 612C. With elongated leadframe subportions, the resistance of the leadframe and the overall gain (in mV/A) of the current sense operations may be increased.

FIG. 6D is an interior view 630 of another example IC package 632. The IC package 632 is an example of the IC package 110 in FIG. 1, the IC package 110A in FIG. 2, or the IC package 304 in FIG. 3. In the example of FIG. 6D, the IC package 632 includes an IC 641 and a leadframe, the leadframe including a first leadframe subportion 642A, a second leadframe subportion 642B, a third leadframe subportion 642C, a fourth leadframe subportion 642D, and a fifth leadframe subportion 642E. In the example of FIG. 6D, the first leadframe subportion 642A, the second leadframe subportion 642B, the third leadframe subportion 642C, the fourth leadframe subportion 642D, and the fifth leadframe subportion 642E may be part of the second leadframe portion 503B in FIGS. 5A and 5B. The first leadframe subportion 642A includes the IS+ terminal. The fifth leadframe subportion 642E includes the IS− terminal. The second leadframe subportion 642B is between the first leadframe subportion 642A and the third leadframe subportion 642C. The fourth leadframe subportion 642D is between the fifth leadframe subportion 642E and the third leadframe subportion 642C. The third leadframe subportion 642C is between the second leadframe subportion 642B and the fourth leadframe subportion 642D. The third leadframe subportion 642C forms a leadframe resistor between the second leadframe subportion 642B and the fourth leadframe subportion 642D.

In the example of FIG. 6D, part of the third leadframe subportion 642C is shown using dashed lined to represent some of the third leadframe subportion 642C being under the IC 641. In some examples, the second leadframe subportion 622B is narrower than the second leadframe subportion 642B and the fourth leadframe subportion 642D and may provide support for the IC 641. The second leadframe subportion 642B and the fourth leadframe subportion 642D are wider than the third leadframe subportion 642C and narrower than the first leadframe subportion 642A and the fifth leadframe subportion 642E. Compared to the IC package 602 of FIG. 6C, the IC package 632 of FIG. 6D has the same terminals and a leadframe has additional subportions or tiers (e.g., five tiers or subportions instead of three as in FIGS. 6B and 6C). With additional tiers or subportions, the resistivity of the leadframe and the overall gain (in mV/A) of current sense operations may be adjusted. In different examples, the number, length, and cross-sectional area of tiers or subportions of a leadframe may vary, which affects resistivity, current density, and thermal characteristics.

In some examples, a package resistor of an IC package is used as a shunt resistor in a current input-voltage output analog current sensor system. A current sensor IC (e.g., the sense circuitry 124 in FIGS. 1 and 2, the IC 504 in FIGS. 5A and 5B, the IC 611 in FIG. 6C, or the IC 641 in FIG. 6D) produces a voltage on its output that amplifies the current passing through its leadframe with a transimpedance gain (V/A). In some examples, the package resistor is part of a leadframe with target parameters (e.g., resistivity, current density, and/or thermal characteristics) on which the current sensor IC die sits. In some examples, the current sensor IC uses mixed signal circuitry to resolve issues arising from using a package resistor with a significant positive temperature coefficient. In some examples, the leadframe is constructed of a copper alloy, the IC die sits on the leadframe and is connected to terminals (e.g., the terminals in FIGS. 6A to 6D) of the package using bondwires. In some examples, the encapsulant (e.g., the encapsulant 510 in FIGS. 5A and 5B) is a black molding compound, which covers the IC, the bondwires, and at least some of the package resistor.

In the described examples, current passes through the package resistor via the IS+ and IS− terminals. In the narrow portion of the leadframe (e.g., the second leadframe portion 612B in FIG. 6B, the second leadframe portion 622B in FIG. 60, or the third leadframe portion 642C in FIG. 6D) forms the package resistor. In some examples, each of the IC packages 402, 602, 632 of FIGS. 6A to 6D may include terminals for power supply and ground. As another option, a REF terminal may be included to support negative current measurements.

In different examples, the resistance value and power rating of a leadframe resistor or package resistor may vary as a function of the resistivity of the leadframe or package resistor material and the dimensions of the leadframe or package resistor. For example, increasing the length of a resistive material can increase the resistive value, while increasing the cross-sectional area of a resistive material can increase the power rating. In some examples, the resistance value of a sense resistor is selected to reduce losses (power consumption) due to sense operations. Without limitation, sense resistors with a resistance value between 200 to 1000 are suitable for sense operations. In some examples, the cross-sectional area of a resistive material is selected to support a target current (e.g., a current flow of 50A) or related power rating for sense operations.

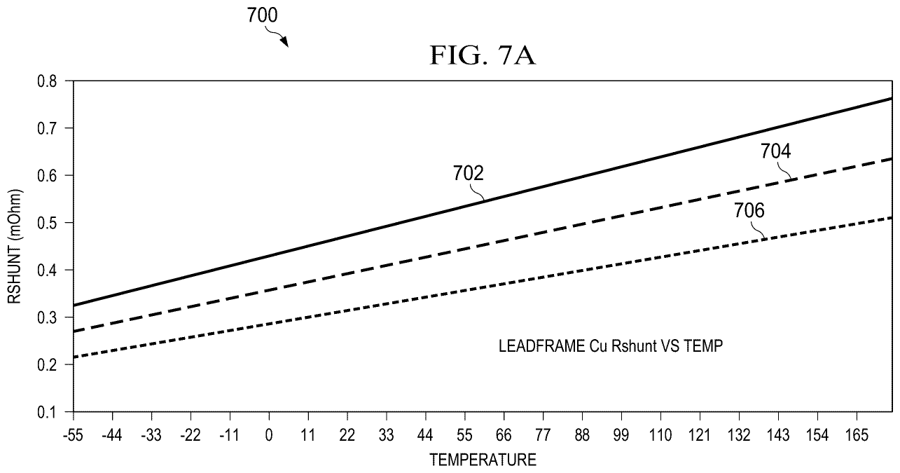

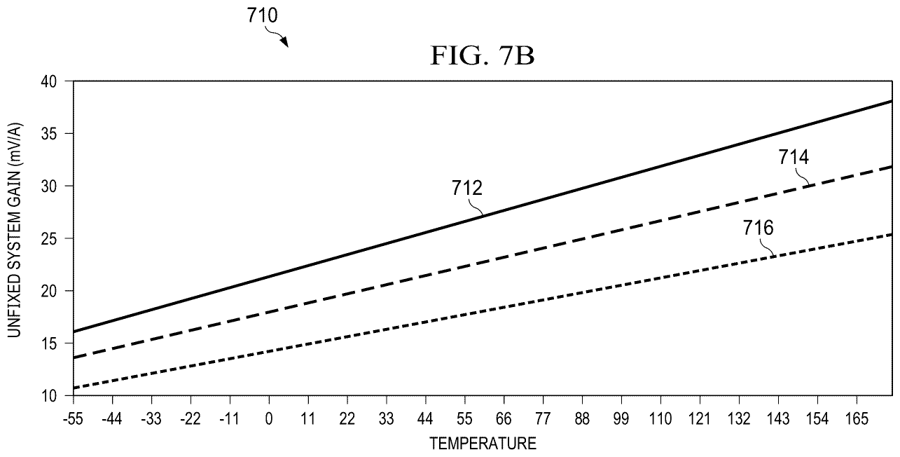

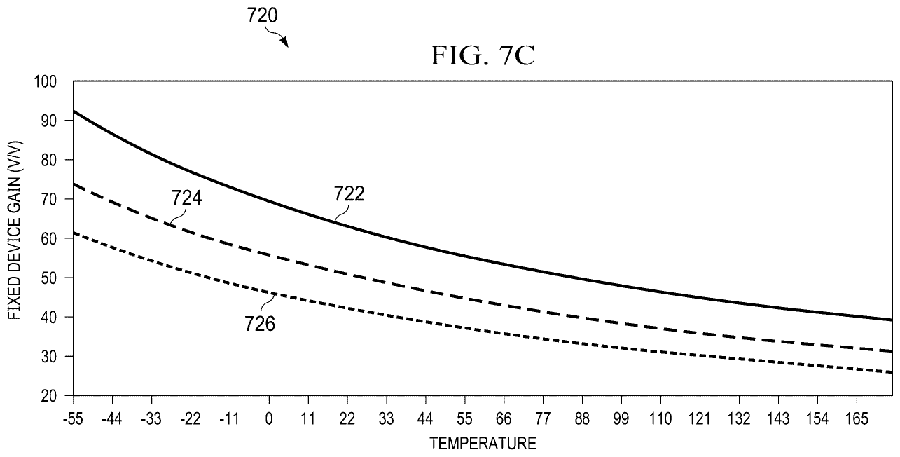

FIG. 7A is a graph 700 of resistance as a function of temperature for an example leadframe resistor. In some examples, the leadframe material, at least a portion of which forms the package resistor, is constructed of a copper alloy material. In such examples, the temperature coefficient may be approximately 4000 ppm/C (0.4%/C). Therefore, the resistance changes with and is directly proportional to its temperature. The line 704 in graph 700 shows a shunt resistance of 0.4 mΩ with a temperature coefficient of (0.4%/C) can change from −55 to 170C. In some scenarios, the leadframe may have tolerance of +/−20%. In graph 700, line 702 shows a shunt resistance of 0.48 mΩ (0.4Ω+20%) as a function of temperature, and line 706 shows a shunt resistance of 0.32 mΩ (0.4Ω−20%) as a function of temperature. In other examples, the temperature coefficient of a package resistor may vary.

FIG. 7B is a graph 710 of system gain as a function of temperature for example sense circuitry. The line 714 in graph 710 shows how temperature affects the overall system gain in mV/A for the 0.4 mΩ shunt resistor of FIG. 7A. In some scenarios, the leadframe may have tolerance of +/−20%. Accordingly, line 712 shows the gain of a shunt resistance of 0.48 mΩ (0.4Ω+20%) as a function of temperature, and line 716 shows the gain of a shunt resistance of 0.32 mΩ (0.4Ω−20%) as a function of temperature.

In the example of FIG. 7A, the package resistor may vary in value from 0.27 mΩ to 0.64 mΩ and the overall gain may vary from 13.6 mV/A to 32 mV/A over the temperature range (e.g., −55° C. to 176° C.). This drift of gain over temperature can cause significant error in the output voltage VOUT from the current sense circuitry. For example, if the input current into the current sense circuitry is 10 A and the current sense circuitry has a gain 20 mV/A (0.4 mOhm×50V/V) and VREF is 2V, the output voltage VOUT is 2.2V (10 A×20 mV/A+2V). However, if the package resistor value reaches 0.64 mΩ at 170C, and the current sensor gain reaches 32 mV/A, the output voltage VOUT of the current sense circuitry becomes 2.32V at 170C instead (10 A×32 mV/A+2V).

In some examples, the current sense circuitry provides dynamic gain/offset calibration. In some examples, the dynamic gain/offset calibration is based on: detecting the temperature of the package resistor; and modifying the voltage gain of the current sense amplifier (in V/V). FIG. 7C is a graph 720 of system gain as a function of temperature for other example sense circuitry. With dynamic gain/offset calibration as in graph 720, the effect of the shunt resistance changing is reduced or eliminated and the overall current sensor gain (in mV/A) is maintained constant over temperature. Specifically, line 724 shows dynamic adjustment of gain for a shunt resistance of 0.4 mΩ as a function of temperature. Line 722 shows the gain of a shunt resistance of 0.48 mΩ (0.4Ω+20%) as a function of temperature. Line 726 shows dynamic adjustment of gain for a shunt resistance of 0.32 mΩ (0.4Ω−20%) as a function of temperature.

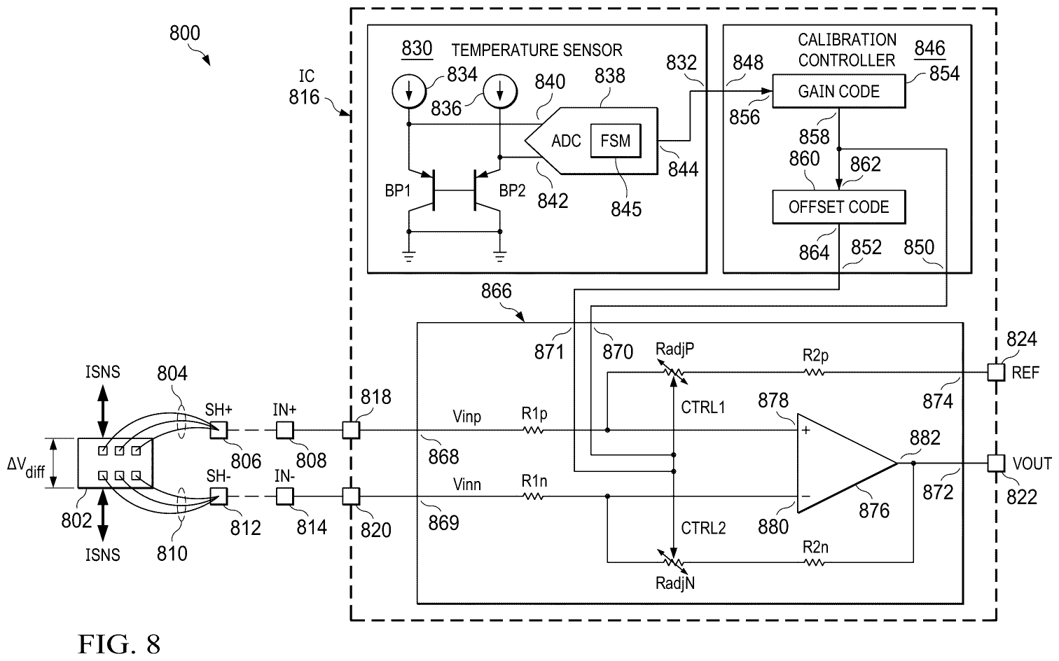

FIG. 8 is a diagram of an example IC package 800. The IC package 800 includes a package resistor 802, first bondwires 804, an SH+ terminal 806, an IN+ terminal 808, second bondwires 810, an SH− terminal 812, an IN− terminal 814, and an IC 816. The package resistor 802 is an example of the package resistor 118 in FIG. 1, the resistor RS1 in FIG. 2, part of the leadframe layer 502 or the second leadframe portion 503B in FIGS. 5A and 5B, the second leadframe portion 612B in FIG. 6B, the second leadframe portion 622B in FIG. 6C, or the third leadframe portion 642C in FIG. 6D. The SH+ terminal 806 is an example of the SH+ terminal in FIGS. 6A to 6D. The IN+ terminal 808 is an example of the IN+ terminal in FIGS. 6A to 6D. The SH− terminal 812 is an example of the SH− terminal in FIGS. 6A to 6D. The IN− terminal 814 is an example of the IN− terminal in FIGS. 6A to 6D. The first bondwires 804 are an example of the first bondwires 614 in FIG. 6B. The second bondwires 810 is an example of the second bondwires 616 in FIG. 6B. The IC 816 is an example of the sense circuitry 124 in FIGS. 1 and 2, the IC 504 in FIGS. 5A and 5B, the IC 534 in FIGS. 5C and 5D, the IC 611 in FIG. 6B, the IC 621 in FIG. 6C, or the IC 641 in FIG. 6D.

In the example of FIG. 8, the IC 816 has a first terminal 818, a second terminal 820, a third terminal 822, and a fourth terminal 824. In some examples, the first terminal 818 of the IC 816 is coupled to the IN+ terminal 808 of the IC package 800. The second terminal 820 of the IC 816 is coupled to the IN− terminal 812 of the IC package 800. The third terminal 822 of the IC 816 is coupled to the OUT terminal (not shown) of the IC package 800.

In the example of FIG. 8, the IC 816 includes temperature sensor circuitry 830, a calibration controller 846, and current sense amplifier circuitry 866. The temperature sensor circuitry 830 has a terminal 832. In some examples, the temperature sensor circuitry 830 includes current sources 834 and 836, transistors BP1 and BP2, and an analog-to-digital converter (ADC) 838 in the arrangement shown. The ADC 838 has a first terminal 840, a second terminal 842, and a third terminal 844. In the example of FIG. 8, the ADC 838 includes a finite state machine (FSM) 845.

The calibration controller 846 has a first terminal 848, a second terminal 850, and a third terminal 852. In some examples, the calibration controller 846 include a gain code control logic 854 and an offset code control logic 860 in the arrangement shown, which may be implemented as digital logic circuitry, for example. The gain code control logic 854 has a first terminal 856 and a second terminal 858. The offset code control logic 860 has a first terminal 862 and a second terminal 864.

The current sense amplifier circuitry 866 has a first terminal 868, a second terminal 869, a third terminal 870, a fourth terminal 871, a fifth terminal 872, and a sixth terminal 874. In some examples, the current sense amplifier circuitry 866 includes an operational amplifier 876, resistors R1p, R1n, R2p, and R2n, and adjustable resistors RadjP and RadjN in the arrangement shown. Each of the resistors R1p, R1n, R2p, and R2n has a respective first terminal and a respective second terminal. Each of the adjustable resistors RadjP and RadjN has a respective first terminal, a respective second terminal, and a respective control terminal. The operational amplifier 876 has a first (non-inverting or “+”) terminal 878, a second (inverting or “−”) terminal 880, and a third terminal 882.

In the example of FIG. 8, a first side of the package resistor 802 is coupled to the SH+ terminal 806 of the IC package 800 via the first bondwires 804. In some examples, a conductive side or target portion of the package resistor (e.g., the leadframe resistor) may be considered as a terminal for the package resistor. In other words, the conductive side or target portion of the package resistor that is used to electrically couple the package resistor to another component may be considered as a terminal for the package resistor. Each package resistor may have, for example, two conductive sides or target portions used as terminals. The SH+ terminal 806 is coupled to the IN+ terminal 808 of the IC package 800. The IN+ terminal 808 is coupled to the first terminal 818 of the IC 816. A second side of the package resistor 802 is coupled to the SH− terminal 812 of the IC package 800 via the second bondwires 810. The SH− terminal 812 is coupled to the IN− terminal 814 of the IC package 800. The IN− terminal 814 is coupled to the second terminal 820 of the IC 816.

The first terminal 868 of the current sense amplifier circuitry 866 is coupled to the first terminal 818 of the IC 816 and the first terminal of the resistor R1p. The second terminal of the resistor R1p is coupled to the first terminal of the adjustable resistor RadjP and the first terminal 878 of the operational amplifier 876. The second terminal of the adjustable resistor RadjP is coupled to the first terminal of the resistor R2p. The second terminal of the resistor R2p is coupled to the sixth terminal 874 of the current sense amplifier circuitry 866 and the fourth terminal 824 of the IC 816.

The second terminal 869 of the current sense amplifier circuitry 866 is coupled to the second terminal 820 of the IC 816 and the first terminal of the resistor R1n. The second terminal of the resistor R1n is coupled to the first terminal of the adjustable resistor RadjN and the second terminal 880 of the operational amplifier 876. The second terminal of the adjustable resistor RadjN is coupled to the first terminal of the resistor R2n. The second terminal of the resistor R2n is coupled to the third terminal 882 of the operational amplifier 876, the sixth terminal 874 of the current sense amplifier circuitry 866, and the fourth terminal 824 of the IC 816.

In the example of FIG. 8, the first terminal of the transistor BP1 is coupled to the current source 834 and the first terminal 840 of the ADC 838. The second terminal of the transistor BP1 is coupled to ground or a ground terminal. The first terminal of the transistor BP2 is coupled to the current source 836 and the second terminal 842 of the ADC 838. The control terminals of the transistors BP1 and BP2 are coupled together. The third terminal 844 of the ADC 838 is coupled to the terminal 832 of the temperature sensor circuitry 830. In other examples, temperature sensor circuitry may vary from the example of FIG. 8.

The first terminal 848 of the calibration controller 846 is coupled to the terminal 832 of the temperature sensor circuitry 830. The second terminal 850 of the calibration controller 846 is coupled to the control terminals of the resistors RadjP and RadjN. The third terminal 852 of the calibration controller 846 is coupled to the control terminals of the resistors RadjP and RadjN. The first terminal 856 of the gain code control logic 854 is coupled to the first terminal 848 of the calibration controller 846. The second terminal 858 of the gain code control logic 854 is coupled to the first terminal 862 of the offset code control logic 860 and the second terminal 850 of the calibration controller 846. The second terminal 864 of the offset code control logic 860 is coupled to the third terminal 852 of the calibration controller 846.

The IC 816 operates to: receive a current sense differential voltage across the first terminal 818 of the IC 816 and the second terminal 820 of the IC 816 responsive to the current through the package resistor 802; and provide VOUT at the third terminal 822 of the IC 816 responsive to the current sense differential voltage, operations of the temperature sensor circuitry 830, operations of the calibration controller 846, and operations of the current sense amplifier circuitry 866. In some examples, the IC 816 operates to: receive a reference voltage VREF at the fourth terminal 824; and adjust VOUT at the third terminal 822 responsive to the current sense differential voltage, operations of the temperature sensor circuitry 830, operations of the calibration controller 846, operations of the current sense amplifier circuitry 866, and VREF (e.g., VOUT=Rₛₕᵤₙₜ*Gain_{CS}+VREF).

The temperature sensor circuitry 830 operates to: provide a differential voltage responsive to an ambient temperature; provide a digital temperature code at the third terminal 844 of the ADC 838 responsive to the differential voltage being applied across the first terminal 840 and the second terminal 842 of the ADC 838; and provide the digital temperature code to the terminal 832 of the temperature sensor circuitry 830.

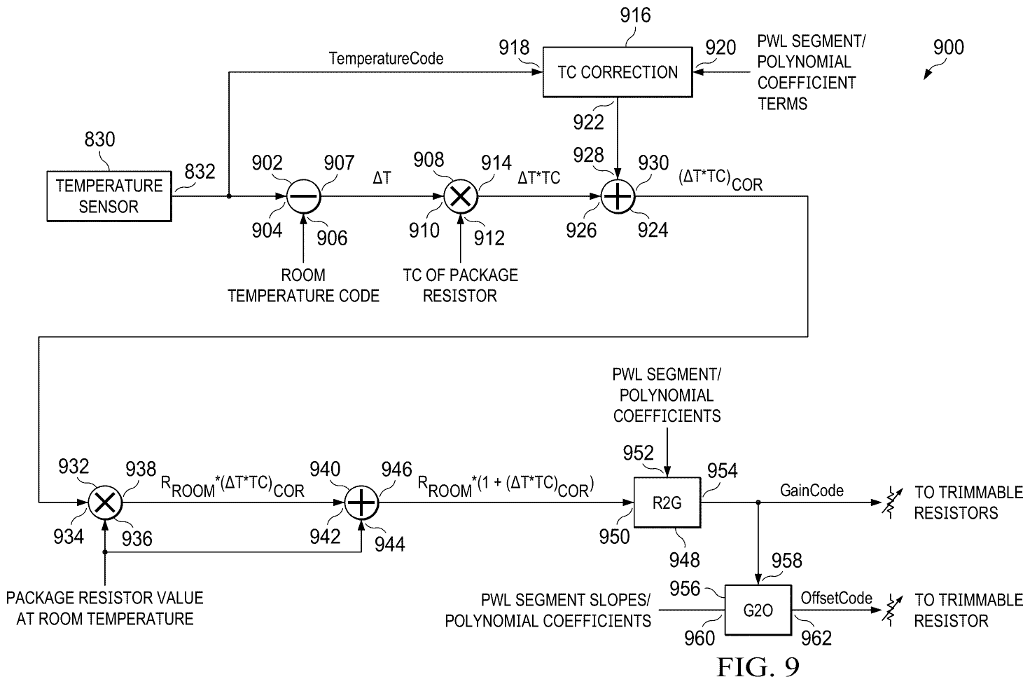

The calibration controller 846 operates to: receive the digital code at the first terminal 848; provide a gain control code at the second terminal 850 responsive to the digital temperature code and operations of the gain code control logic 854; and provide an offset control code at the third terminal 852 responsive to the gain control code and operations of the offset code control logic 860. In some examples, the gain code control logic 854 operates to: receive the digital temperature code (representing the temperature of the package resistor); apply the digital temperature code to a math engine (described in FIG. 9); and calculate a gain control code responsive to the digital temperature code and operations of the math engine. In some examples, the gain control code adjusts the value adjustable resistors so that the gain of current sense operations follows a negative curve as function o temperature as in the example of FIG. 7C. In some examples, the offset code control logic 860 operates to: receive the gain control code; and adjust an offset control code responsive to the gain control code.

The current sense amplifier circuitry 866 operates to: receive the current sense differential voltage across the first terminal 868 and the second terminal 869; receive a gain control code at the third terminal 870; receive an offset control code at the fourth terminal 871; and provide VOUT at the fifth terminal 872 responsive to the current sense differential voltage, the gain control code, the offset control code, the arrangement of the resistors R1p, RadjP, R2p, R1n, RadjN, and R2n, and operations of the operational amplifier 876. In some examples, the current sense amplifier circuitry 866 operates to: receive VREF at the sixth terminal 874; and adjust VOUT at the fifth terminal 872 responsive to VREF, the current sense differential voltage, the gain control code, the offset control code, the arrangement of the resistors R1p, RadjP, R2p, R1n, RadjN, and R2n, and operations of the operational amplifier 876.

FIG. 9 is a diagram 900 of an example sense circuit calibration technique. In the example of FIG. 9, the diagram 900 includes the temperature sensor circuitry 830, a subtraction block 902, a first multiplier block 908, a temperature coefficient (TC) correction block 916, a first summation block 924, a second multiplier block 932, a second summation block 940, a gain adjustment (R2G) block 948, and an offset adjustment (G2O) block 956.

The temperature sensor circuitry 830 has the terminal 832. The subtraction block 902 has a first terminal 904, a second terminal 906, and a third terminal 907. The first multiplier block 908 has a first terminal 910, a second terminal 912, and a third terminal 914. The TC correction block 916 has a first terminal 918, a second terminal 920, and a third terminal 922. The first summation block 924 has a first terminal 926, a second terminal 928, and a third terminal 930. The second multiplier block 932 has a first terminal 934, a second terminal 936, and a third terminal 938. The second summation block 940 has a first terminal 942, a second terminal 944, and a third terminal 946. The R2G block 948 has a first terminal 950, a second terminal 952, and a third terminal 954. The G2O block 956 has a first terminal 958, a second terminal 960, and a third terminal 962.

The terminal 832 of the temperature sensor circuitry 830 is coupled to the first terminal 904 of the subtraction block 902 and the first terminal 918 of the TC correction block 916. The third terminal 907 of the subtraction block 902 is coupled to the first terminal of the first multiplier block 908. The third terminal 914 of the first multiplier block 908 is coupled to the first terminal 926 of the first summation block 924. The second terminal 928 of the first summation block 924 is coupled to the third terminal 922 of the TC correction block 916. The third terminal 930 of the first summation block 924 is coupled to the first terminal 934 of the second multiplier block 932. The third terminal 938 of the second multiplier block 932 is coupled to the first terminal 942 of the second summation block 940. The third terminal 946 of the second summation block 940 is coupled to the first terminal 950 of the R2G block 948. The third terminal 954 of the R2G block 948 is coupled to control terminals of adjustable resistors (e.g., the adjustable resistors RadjP and RadjN) and the first terminal 958 of the G2O block 956. The third terminal 962 of the G2O block 956 is coupled to control terminals of adjustable resistors (e.g., the adjustable resistors RadjP and RadjN).

In some examples, a leadframe with a shunt resistor (e.g., the package resistor 802), bondwires, package pins, and/or PCB traces convert an input current into a differential voltage that is then provided to Vinp/Vinn bondpads (e.g., the first and second terminals 818 and 820 herein) of the IC. In some examples, the IC 816 includes an amplifier (e.g., the operational amplifier 876 that converts the input differential voltage to a single ended voltage (e.g., VOUT herein). In different examples, the amplifier topology and feedback arrangement may vary. Regardless of the particular amplifier topology and feedback arrangement, the amplifier operates to gain up the differential voltage to an output voltage. In the example of FIG. 8, the current sense amplifier circuitry 866 provides a gain Gain_{Amp}=R2/R1.

In the example of FIG. 8, the gain of the current sense amplifier circuitry 866 is adjustable. Specifically, the adjustable resistors RadjP and RadjN may be used as potentiometers with tap points being controlled by digital codes that come from the calibration controller 846 as part of a dynamic drift correction system. In the example of FIG. 8, a section of each of adjustable resistors RadjP and RadjN to the right of the tap point is in series with a respective R2 resistor (R2p and R2n) so each R2 value can be considered as (R2+Radj_right). The section of the adjustable resistors RadjP and RadjN to the left of the tap point is in series with a respective R1 resistor (R1p and R1n) so each R1 value can be considered to be (R1+Radj_left). Hence the gain of the amplifier in this architecture is given as (R2+Radj_right)/(R1+Radj_left).

The gain control code shifts the tap point left and right equally for both of the adjustable resistors RadjP and RadjN and changes the gain of the amplifier. Depending on the architecture of the current sense amplifier circuitry 866, the gain adjustment may vary. Regardless of such variations, the calibration controller 846 may provide a digital gain control code for gain adjustments.

In some examples, the resistor network of the current sense amplifier circuitry 866 may have inherent mismatches due to the semiconductor manufacturing process. Example mismatch may be approximately +/−0.2%. To account for resistor mismatch and related output error, the calibration controller 846 may provide the offset control code. As the gain control code changes the value of the adjustable resistors RadjP and RadjN and subsequently the gain of the amplifier, the offset error of the amplifier also changes since the resistor network is changing. The calibration controller 846 may therefore determine the offset control code to change the values of the resistors in the resistor network to account for mismatch.

In some examples, the offset control code moves the tap points on the adjustable resistors RadjP and RadjN independently from the gain control code. In some examples, as the tap point for the RadjP moves left, the tap point for the adjustable resistor RadjN moves right. This effectively changes the contribution of each adjustable resistor to the R2 and R1 resistors on the P and N side with the goal of maintain a target R2/R1 ratio on both the P and N side resistors. Depending on the architecture of the current sense amplifier circuitry 866, offset correction may vary. Regardless of such variations, the calibration controller 846 may provide a digital offset control code for offset adjustments.

In some examples, the temperature sensor circuitry 830 is an on-chip temperature sensor with mixed signal circuitry to convert the IC temperature into the digital temperature code. The digital temperature code is then sent to the calibration controller 846, which can adjust the gain control code and the offset control code dynamically.

In the example of FIG. 9, the temperature sensor circuitry 830 operates to: provide a digital temperature code (TemperatureCode) at the terminal 832 responsive to an ambient temperature. The subtraction block 902 operates to: receive the digital temperature code at the first terminal 904; receive a room temperature code at the second terminal 906; and provide a relative temperature value (e.g., ΔT=the digital temperature code minus the room temperature code) at the third terminal 907 responsive to the digital temperature code and the room temperature code. The first multiplier block 908 operates to: receive the relative temperature value at the first terminal 910; receive a TC value for the package resistor at the second terminal 912; and provide a first multiplication result (e.g., ΔT*TC) at the third terminal 914 responsive to the relative temperature value and the temperature coefficient of the package resistor. The TC correction block 916 operates to: receive the digital temperature code at the first terminal 918; receive piecewise linear (PWL) segments or polynomial coefficients at the second terminal 920; and provide a corrected digital temperature code at the third terminal 922 responsive to the digital temperature code and the PWL segments or polynomial coefficient. The first summation block 924 operates to: receive the first multiplication result at the first terminal 926; receive the corrected digital temperature code at the second terminal 928; and provide a first summation value (e.g., (ΔT*TC)_{COR}, where (ΔT*TC)_{COR} is a corrected summation value that accounts for changes to TC) at the third terminal 930 responsive to the first multiplication result and the corrected digital temperature code.

The second multiplier block 932 operates to: receive the first summation result at the first terminal 934; receive the package resistor value at the second terminal 936; and provide a second multiplication result at the third terminal 938 responsive to the first summation result and the package resistor value at room temperature (R_{ROOM}). In some examples, the second multiplication result is given as: R_{ROOM}*(ΔT*TC)_{COR}. The second summation block 940 operates to: receive the second multiplication result at the first terminal 942; receive R_{ROOM} at the second terminal 944; and provide a second summation result at the third terminal 946 responsive to the second multiplication result and R_{ROOM}. In some examples, the second summation result is given as: R_{ROOM}*(1+(ΔT*TC)_{COR}) The R2G block 948 operates to: receive the second summation result at the first terminal 950; receive PWL segments or polynomial coefficients at the second terminal 952; and provide a gain control code (GainCode) at the third terminal 954 responsive to the second summation result and the PWL segment/polynomial coefficients. The G2O block 956 operates to: receive the gain control code at the first terminal 958; receive PWL segment/polynomial coefficients at the second terminal 960; and provide an offset control code (OffsetCode) at the third terminal 962 responsive to the gain control code and the PWL segment/polynomial coefficients.

In some examples, temperature sensor circuitry (e.g., the temperature sensor circuitry 830) includes bipolar transistors (e.g., the transistors BP1 and BP2), an ADC (e.g., the ADC 838) and a controlling digital state machine (e.g., the FSM 845). The ADC receives as its input the difference in the Vbe voltages (dVbe) between the bipolar transistors, which have different current densities. This dVbe value is proportional to temperature and can be used reliably to sense temperature. In some examples, the bipolar transistors may also be used to generate a reference voltage (VREF_{BP}) for the ADC that stays constant over temperature to within a threshold tolerance. In such examples, the ADC uses the dVbe voltage and VREF_{BP} to produce a digital temperature code that is proportional to the ratio of the dVbe and VREF_{BP} (TemperatureCode=A*dVbe/Vref+B where A and B are temperature sensor gain and offset trims that can be programmed during production in order to achieve a target digital code output). In other examples, temperature sensor circuitry (e.g., the temperature sensor circuitry 830) may generate a digital temperature code proportional to the die temperature using other techniques. If the IC is placed on top of a leadframe resistor, the temperature of the IC and hence the output of the temperature sensor circuitry is equal to the temperature of the leadframe resistor within some reasonable tolerance.

In some examples, the digital temperature code is used as an input to calibration controller, which may obtain the gain control code and the offset control code using the technique described in FIG. 9. To account for changes to the temperature coefficient of the package resistor, a TC correction (e.g., the TC correction block 916) is applied. In some examples, the TC variance as a function of temperature is non-linear. In such examples, TC correction applies a non-linear correction. In some examples, the TC correction models the error due to changes in TC and applies a correction based on the digital temperature code. In some examples, TC correction uses a piecewise linear function to model the non-linear TC error function. In other examples, TC correction uses a polynomial function that closest approximates the error function. Regardless of the particular technique used, some predetermined inputs may be applied. For example, the PWL function may be implemented using slopes in predetermined segments over the operating temperature range of the device. The segment slopes of the PWL function can be configured and programmed during production based on characterization analysis of the package resistor. As another examples, the coefficient terms of the polynomial function may be trimmed based on characterization of the package resistor.

In some examples, the R2G block 948 may use a piecewise linear approximation of the function that defines the relationship between the package resistor value at a specific temperature and the digital gain code needed to achieve a target voltage gain at that temperature. In other examples, the R2G block 948 may use a higher order polynomial to define the relationship between the package resistor value at a specific temperature and the digital gain code needed to achieve a target voltage gain at that temperature. In some examples, the R2G function is based on the architecture of the current sensor such that the segments (in the piecewise linear case) or the coefficients (in the polynomial case) do not need to be adjusted. In other examples, the R2G function may be predetermined and programmed.

In some examples, the G2O block 956 is implemented using a piecewise linear approximation of the function that defines the relationship between how the offset error of the amplifier changes as its gain changes with temperature. In other examples, the G2O block 956 is implemented using a higher order polynomial that models the same function. Because the amplifier gain changes as a function of the gain control code, the gain control code from the R2G block 948 may be used as an input to the G2O block 956, which determines an offset control code that minimize the offset error. The digital offset code is then output to the adjustable resistors to equalize the ratio of the p-side and n-side resistors in order to minimize the offset error at the output of the amplifier.

In some examples, current sense circuitry (e.g., the sense circuitry 124 in FIGS. 1 and 2, the IC 504 in FIGS. 5A and 5B, the IC 611 in FIG. 6B, the IC 621 in FIG. 6C, the IC 641 in FIG. 6D, or the IC 816 in FIG. 8) maintains the overall gain (e.g., in mV/A) constant over temperature and minimizes offset error over temperature. In an example scenario, as the temperature increases, the resistance of the package resistor increases, and the voltage differential created across the terminals of the current sense circuitry for the same current increases. In such scenarios, the output (e.g., VOUT herein) of the current sense circuitry increases due to the change in the package resistor value and represents an incorrect current sense value.

To minimize such error, temperature sensor circuitry (e.g., temperature sensor circuitry 830) detects the increase in temperature and provides a digital temperature code that is proportional to temperature to the calibration controller 846. The calibration controller 846 uses the digital temperature code and various preprogrammed value inputs (e.g., PWL segments or polynomial coefficient terms) to determine a gain control code that adjusts the value of the adjustable resistors in the resistance network of the amplifier in order to decrease the gain of the amplifier. With the correction, the overall system gain (in mV/A) stays the same, resulting in VOUT staying the same as if value of the package resistor had not changed with temperature. Also, when the package resistor value changes, offset error is introduced at the output of the amplifier due to the mismatch contribution to the P-side and N-side resistors changing as the gain changes (making the ratio of the P-side and N-side different as the gain changes). Accordingly, the calibration controller 846 may also provide an offset correct code to adjust the adjustable resistors to equalize the P-side and N-side resistor ratios and remove the offset error.

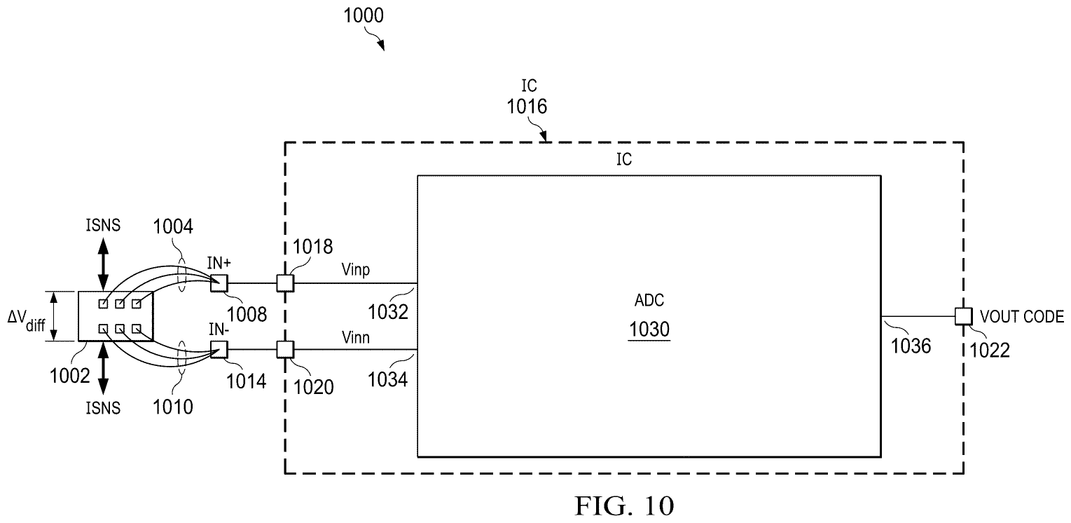

FIG. 10 is a diagram of an example IC package 1000. The IC package 1000 includes a package resistor 1002, first bondwires 1004, an IN+ terminal 1008, second bondwires 1010, an IN− terminal 1014, and an IC 1016. The package resistor 1002 is an example of the package resistor 118 in FIG. 1, the resistor RS1 in FIG. 2, part of the leadframe layer 502 or the second leadframe portion 503B in FIGS. 5A and 5B, the second leadframe portion 612B in FIG. 6B, the second leadframe portion 622B in FIG. 6C, or the third leadframe portion 642C in FIG. 6D. The IN+ terminal 1008 is an example of the IN+ terminal in FIGS. 6A to 6D. The IN− terminal 1014 is an example of the IN− terminal in FIGS. 6A to 6D. The first bondwires 1004 are an example of the first bondwires 614 in FIG. 6B. The second bondwires 1010 is an example of the second bondwires 616 in FIG. 6B. The IC 1016 is an example of the sense circuitry 124 in FIGS. 1 and 2, the IC 504 in FIGS. 5A and 5B, the IC 534 in FIGS. 5C and 5D, the IC 611 in FIG. 6B, the IC 621 in FIG. 60, or the IC 641 in FIG. 6D.

In the example of FIG. 10, the IC 1016 has a first terminal 1018, a second terminal 1020, and a third terminal 1022. In some examples, the first terminal 1018 of the IC 1016 is coupled to the IN+ terminal 1008 of the IC package 1000. The second terminal 1020 of the IC 816 is coupled to the IN− terminal 1014 of the IC package 1000. The third terminal 1022 of the IC 1016 is coupled to an output terminal (not shown) of the IC package 1000.

In the example of FIG. 10, a first side of the package resistor 1002 is coupled to the IN+ terminal 1008 of the IC package 1000 via the first bondwires 1004. The IN+ terminal 1008 is coupled to the first terminal 1018 of the IC 1016. A second side of the package resistor 1002 is coupled to the IN− terminal 1014 of the IC package 1000 via the second bondwires 1010. The IN− terminal 1014 is coupled to the second terminal 1020 of the IC 1016.

In the example of FIG. 10, the IC 1016 includes an ADC 1030. The ADC 1030 has a first terminal 1032, a second terminal 1034, and a third terminal 1036. The first terminal 1032 of the ADC 1030 is coupled to the first terminal 1018 of the IC 1016. The second terminal 1034 is coupled to the second terminal 1020 of the IC 1016. The third terminal 1036 of the ADC 1030 is coupled to the third terminal 1022 of the IC 1016. In different examples, the ADC topology may vary.

The IC package 1000 operates to receive a current ISNS through the package resistor 1002. The current ISNS results in a differential voltage (Vinp-Vinn) across the package resistor 1002. The Vinp voltage is provided to the first terminal 1032 of the ADC 1030 via the first bondwires 1004, the IN+ terminal 1008 of the IC package 1000, the first terminal 1018 of the IC 1016. The Vinn voltage is provided to the second terminal 1034 of the ADC 1030 via the second bondwires 1010, the IN+ terminal 1014 of the IC package 1000, the second terminal 1020 of the IC 1016. The ADC 1030 operates to: receive Vinp at the first terminal 1032; receive Vinn at the second terminal 1034; and provide a digital code at the third terminal 1036 responsive to the difference between Vinp and Vinn. With the IC package 1000 of FIG. 10, a controller (e.g., the controller 132 in FIG. 1, or the controller 232 in FIG. 2) or other circuitry receives the digital code and interprets the digital code as a current sense signal (e.g., S1_ISNS in FIG. 1 or 2).

In some examples, an IC package (e.g., the IC package 110 in FIG. 1, the IC package 110A in FIG. 2, the IC package 304 in FIG. 3, the IC package 402 in FIGS. 4A, 4B, 5A, 5B, 6A, and 6B, the IC package 531 in FIGS. 5C and 5D, the IC package 602 in FIG. 6C, the IC package 632 in FIG. 6D, the IC package 800 in FIG. 8, or the IC package 1000 in FIG. 10) includes: a package resistor (e.g., the package resistor 118 in FIG. 1, RS1 in FIG. 2, package resistor 542 in FIGS. 5C and 5D, the leadframe resistor integrated with the second leadframe subportion 612B in FIG. 6B, the leadframe resistor integrated with the second leadframe subportion 622B in FIG. 60, the leadframe resistor integrated with the third leadframe subportion 642C in FIG. 6D, the package resistor 802 in FIG. 8, or the package resistor 1002 in FIG. 10) having a first terminal (e.g., the first terminal 120 in FIG. 1 or related terminals in FIGS. 2, 50, 5D, 6B, 6C, 6D, 8, and 10) and a second terminal (e.g., the second terminal 122 in FIG. 1 or related terminals in FIGS. 2, 50, 5D, 6B, 60, 6D, 8, and 10); and an IC (e.g., the IC 504 in FIGS. 5A and 5B, the IC 534 in FIGS. 5C and 5D, the IC 611 in FIG. 6B, the IC 621 in FIG. 6C, the IC 641 in FIG. 6D, the IC 816 in FIG. 8, or the IC 1016 in FIG. 10) separate from and coupled to the package resistor. The IC includes sense circuitry (e.g., the sense circuitry 124 in FIGS. 1 and 2, the current sense amplifier circuitry 866 in FIG. 8, or the ADC 1030 in FIG. 10) having a first terminal (e.g., the first terminal 126 in FIG. 1 or related terminals in FIGS. 2, 8 and 10) and a second terminal (e.g., the second terminal 128 in FIG. 1 or related terminals in FIGS. 2, 8, and 10). The first terminal of the sense circuitry is coupled to the first terminal of the package resistor. The second terminal of the sense circuitry is coupled to the second terminal of the package resistor.

In some examples, the IC has a first terminal (e.g., the first terminal 818 in FIG. 8) and a second terminal (e.g., the second terminal 820 in FIG. 8). The first terminal of the IC is coupled to the first terminal of the package resistor via a first bondwire (e.g., one of the first bondwires 804 in FIG. 8). The second terminal of the IC is coupled to the second terminal of the package resistor via a second bondwire (e.g., one of the second bondwires 810 in FIG. 8). In other examples, the first terminal of the IC is coupled to the first terminal of the package resistor via first bondwires (e.g., the first bondwires 804 in FIG. 8), and the second terminal of the IC is coupled to the second terminal of the package resistor via second bondwires (e.g., the second bondwires 810 in FIG. 8).

In some examples, the package resistor is a leadframe resistor (e.g., integrated with the second leadframe portion 503B in FIGS. 5A and 5B, integrated with the second leadframe subportion 612B in FIG. 6B, integrated with the second leadfame subportion 622B in FIG. 6C, integrated with the third leadframe subportion 642C in FIG. 6D). In such examples, the IC package includes a leadframe with a first leadframe subportion (e.g., the first leadframe subportion 612A in FIG. 6B, or the first leadframe subportion 622A in FIG. 6C), a second leadframe subportion (e.g., the second leadframe subportion 612B in FIG. 6B, or the second leadframe subportion 622B in FIG. 6C), and a third leadframe subportion (e.g., the third leadframe subportion 612C in FIG. 6B, or the third leadframe subportion 622C in FIG. 6C). The second leadframe subportion is between the first and third leadframe subportions. The third leadframe subportion forms the leadframe resistor. In some examples, the second leadframe subportion is narrower than the first and third leadframe subportions.

In other examples, the IC package includes a leadframe with a first leadframe subportion (e.g., the first leadframe subportion 642A in FIG. 6D), a second leadframe subportion (e.g., the second leadframe subportion 642B in FIG. 6D), a third leadframe subportion (e.g., the third leadframe subportion 642C in FIG. 6D), a fourth leadframe subportion (e.g., the fourth leadframe subportion 642D in FIG. 6D), and a fifth leadframe subportion (e.g., the fifth leadframe subportion 642E in FIG. 6D). The second leadframe subportion is between the first and third leadframe subportions. The fourth leadframe subportion is between the third and fifth leadframe subportions. The third leadframe subportion forms the leadframe resistor. In some examples, the second and fourth leadframe subportions are narrower than the first and fifth leadframe subportions, and the third leadframe subportion is narrower than the second and fourth leadframe subportions.

In some examples, the sense circuitry includes temperature sensor circuitry (e.g., the temperature sensor circuitry 830 in FIGS. 8 and 9), a current sense amplifier (e.g., the current sense amplifier circuitry 866 in FIG. 8) with adjustable resistors (e.g., the adjustable resistors RadjP and RadjN in FIG. 8), and a calibration controller (e.g., the calibration controller 846 in FIG. 8, or related components/operations in FIG. 9) coupled to the temperature sensor circuitry and the adjustable resistors. The temperature sensor circuitry is configured to provide a digital temperature code (e.g., TemperatureCode in FIG. 9) proportional to the temperature of the package resistor. The calibration controller is configured to: receive the digital temperature code; determine a gain adjustment (e.g., using the gain code control logic 854 or related operations in FIG. 9) responsive to the digital temperature code; determine an offset adjustment (e.g., using the offset code control logic 860 in FIG. 8, or related operations in FIG. 9) responsive to the gain adjustment; and provide a control signal (e.g., GainCode and/or OffsetCode in FIG. 9) to the adjustable resistors responsive to the gain adjustment and the offset adjustment. In some examples, the sense circuitry is configured to: receive a current sense signal using the package resistor; and output an amplified current sense signal based on the received current sense signal and calibration of the adjustable resistors by the calibration controller.

In some examples, an IC package includes: a leadframe with an integrated leadframe resistor having a first terminal (e.g., the first terminal 615A in FIG. 6B) and a second terminal (e.g., the second terminal 615B in FIG. 6B); and an IC (e.g., the IC 611 in FIG. 6B or the IC 816 in FIG. 8) on the leadframe resistor. The IC has a first terminal (e.g., the first terminal 818 in FIG. 8) coupled to the first terminal of the leadframe resistor and a second terminal (e.g., the second terminal 820 in FIG. 8) coupled to the second terminal of the leadframe resistor. In some examples, the IC has a third terminal (e.g., the third terminal 822 in FIG. 8) and includes sense circuitry (e.g., the sense circuitry 124 in FIGS. 1 and 2, or the current sense amplifier circuitry 866 in FIG. 8) having a first terminal (e.g., the first terminal 126 in FIG. 1, or the first terminal 868 of the current sense amplifier circuitry 866 in FIG. 8), a second terminal (e.g., the second terminal 128 in FIG. 1, or the second terminal 869 of the current sense amplifier circuitry 866 in FIG. 8), and a third terminal (e.g., the third terminal 130 in FIG. 1, or the third terminal 872 of the current sense amplifier circuitry 866 in FIG. 8). The first terminal of the IC is coupled to the first terminal of the sense circuitry. The second terminal of the IC is coupled to the second terminal of the sense circuitry. The third terminal of the IC is coupled to the third terminal of the sense circuitry.

In some examples, the sense circuitry includes an ADC (e.g., the ADC 1030 in FIG. 10) configured to provide a digital output responsive to a voltage differential across the leadframe resistor. In some examples, the sense circuitry includes current sense circuitry including temperature sensor circuitry (e.g., the temperature sensor circuitry 830 in FIG. 8), a current sense amplifier with adjustable resistors (e.g., the current sense amplifier circuitry 866 in FIG. 8), and a calibration controller (e.g., the calibration controller 846 in FIG. 8) coupled to the temperature sensor circuitry and the adjustable resistors.

In some examples, the temperature sensor circuitry is configured to provide a digital temperature code proportional to temperature of the leadframe resistor. In such examples, the calibration controller is configured to: receive the digital temperature code; determine a gain adjustment responsive to the digital temperature code; determine an offset adjustment responsive to the gain adjustment; and provide a control signal to the adjustable resistors responsive to the gain adjustment and the offset adjustment.

In some examples, an IC package includes: a package resistor (e.g., the package resistor 118 in FIG. 1, RS1 in FIG. 2, package resistor 542 in FIGS. 5C and 5D, the leadframe resistor integrated with the second leadframe subportion 612B in FIG. 6B, the leadframe resistor integrated with the second leadframe subportion 622B in FIG. 6C, the leadframe resistor integrated with the third leadframe subportion 642C in FIG. 6D, the package resistor 802 in FIG. 8, or the package resistor 1002 in FIG. 10) having first and second terminals; and an IC. The IC includes: an amplifier (e.g., the current sense amplifier circuitry 866 in FIG. 8) and a calibration controller (e.g., the calibration controller 846 in FIG. 8). The amplifier has a first terminal (e.g., the first terminal 868 of the current sense amplifier circuitry 866 in FIG. 8) coupled to the first terminal of the package resistor and has a second terminal (e.g., the second terminal 869 of the current sense amplifier circuitry 866 in FIG. 8) coupled to the second terminal of the package resistor. The amplifier includes adjustable circuitry (e.g., the adjustable resistors RadjP and RadjN in FIG. 8) configured to adjust a gain of the amplifier. The adjustable circuitry has an input (e.g., the respective control terminals of the adjustable resistors RadjP and RadjN in FIG. 8). The calibration controller includes gain control circuitry (e.g., the gain code control logic 854 in FIG. 8, or related components/operations in FIG. 9) having an output (e.g., the second terminal 858 in FIG. 8) coupled to the input of the adjustable circuitry. The gain control circuitry is configured to provide a calibration setting, at the output, responsive to a digital temperature code (TemperatureCode in FIG. 9).

In some examples, the IC includes: temperature sensor circuitry (e.g., the temperature sense circuitry 830 in FIG. 8) having an output (e.g., the terminal 832 in FIG. 8) coupled to an input (e.g., the first terminal 856 of the gain code control logic 854 in FIG. 8) of the gain control circuitry; a current sense amplifier (e.g., the current sense amplifier circuitry 866 in FIG. 8) with adjustable resistors (e.g., the adjustable resistors RadjP and RadjN in FIG. 8); and a calibration controller (e.g., the calibration controller 846 in FIG. 8) coupled to the temperature sensor circuitry and the adjustable resistors. The temperature sensor circuitry is configured to provide the digital temperature code.

In some examples, the calibration controller (e.g., the calibration controller 846 in FIG. 8, or related components/operations in FIG. 9) includes offset control circuitry (e.g., the offset code control logic 860 in FIG. 8, or related components/operations in FIG. 9) and the calibration controller is configured to determine the calibration setting based on a temperature coefficient correction and based on operations of the offset control circuitry. In some examples, the operations of the offset control circuitry include receiving a gain control code and adjusting an offset control code responsive to the gain control code.

In some examples, the calibration controller (e.g., the calibration controller 846 in FIG. 8, or related components/operations in FIG. 9) is configured to determine the calibration setting based on a piecewise linear function or a polynomial function. In some examples, the calibration controller is configured to determine the calibration setting based on a room temperature value and a package resistor value at the room temperature value.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An integrated circuit (IC) package comprising:
a package resistor having a first terminal and second terminal; and
an IC separate from and coupled to the package resistor, the IC including:
sense circuitry having a first terminal and a second terminal, the first terminal of the sense circuitry coupled to the first terminal of the package resistor, the second terminal of the sense circuitry coupled to the second terminal of the package resistor.

2. The IC package of claim 1, wherein the IC has a first terminal and a second terminal, the first terminal of the IC is coupled to the first terminal of the package resistor via a first bondwire, and the second terminal of the IC is coupled to the second terminal of the package resistor via a second bondwire.

3. The IC package of claim 1, wherein the IC has a first terminal and a second terminal, the first terminal of the IC is coupled to the first terminal of the package resistor via first bondwires, and the second terminal of the IC is coupled to the second terminal of the package resistor via second bondwires.

4. The IC package of claim 1, wherein the package resistor is a leadframe resistor.

5. The IC package of claim 4, further comprising a leadframe including a first leadframe subportion, a second leadframe subportion, and a third leadframe subportion, the second leadframe subportion between the first and third leadframe subportions, the third leadframe subportion forming the leadframe resistor.

6. The IC package of claim 5, wherein the second leadframe subportion is narrower than the first and third leadframe subportions.

7. The IC package of claim 4, further comprising a leadframe including a first leadframe subportion, a second leadframe subportion, a third leadframe subportion, a fourth leadframe subportion, and a fifth leadframe subportion, the second leadframe subportion between the first and third leadframe subportions, the fourth leadframe subportion between the third and fifth leadframe subportions, the third leadframe subportion forming the leadframe resistor, the second and fourth leadframe subportions are narrower than the first and fifth leadframe subportions, and the third leadframe subportion is narrower than the second and fourth leadframe subportions.

8. The IC package of claim 1, wherein the sense circuitry includes temperature sensor circuitry, a current sense amplifier with adjustable resistors, and a calibration controller coupled to the temperature sensor circuitry and the adjustable resistors, the temperature sensor circuitry is configured to provide a digital temperature code proportional to the temperature of the package resistor, and the calibration controller is configured to:
receive the digital temperature code;
determine a gain adjustment responsive to the digital temperature code;
determine an offset adjustment responsive to the gain adjustment; and
provide a control signal to the adjustable resistors responsive to the gain adjustment and the offset adjustment.

9. The IC package of claim 8, wherein the sense circuitry is configured to:
receive a current sense signal using the package resistor; and
output an amplified current sense signal based on the received current sense signal and calibration of the adjustable resistors by the calibration controller.

10. An integrated circuit (IC) package comprising:
a leadframe including an integrated leadframe resistor having a first terminal and a second terminal; and
an IC on the leadframe resistor, the IC having a first terminal coupled to the first terminal of the leadframe resistor and a second terminal coupled to the second terminal of the leadframe resistor.

11. The IC package of claim 10, wherein the IC has a third terminal and includes sense circuitry having a first terminal, a second terminal, and a third terminal, the first terminal of the IC coupled to the first terminal of the sense circuitry, the second terminal of the IC coupled to the second terminal of the sense circuitry, and the third terminal of the IC coupled to the third terminal of the sense circuitry.

12. The IC package of claim 10, wherein the leadframe includes a first lead subportion, a second leadframe subportion, and a third leadframe subportion, the second leadframe subportion between the first and third leadframe subportions, the second leadframe subportion forming the leadframe resistor, and the second leadframe subportion narrower than the first and third leadframe subportions.

13. The IC package of claim 11, wherein the sense circuitry includes an analog-to-digital converter (ADC) configured to provide a digital output responsive to a voltage differential across the leadframe resistor.

14. The IC package of claim 11, wherein the sense circuitry includes current sense circuitry, the current sense circuitry including temperature sensor circuitry, a current sense amplifier with adjustable resistors, and a calibration controller coupled to the temperature sensor circuitry and the adjustable resistors.

15. The IC package of claim 14, wherein the temperature sensor circuitry is configured to provide a digital temperature code proportional to temperature of the leadframe resistor, and the calibration controller is configured to:
receive the digital temperature code;
determine a gain adjustment responsive to the digital temperature code;
determine an offset adjustment responsive to the gain adjustment; and
provide a control signal to the adjustable resistors responsive to the gain adjustment and the offset adjustment.

16. An integrated circuit (IC) package comprising:
a package resistor having first and second terminals; and
an IC including:
an amplifier having a first terminal coupled to the first terminal of the package resistor and having a second terminal coupled to the second terminal of the package resistor, the amplifier including adjustable circuitry configured to adjust a gain of the amplifier, the adjustable circuitry having an input; and
a calibration controller including gain control circuitry having an output coupled to the input of the adjustable circuitry, the gain control circuitry configured to provide a calibration setting, at the output, responsive to a digital temperature code.

17. The IC package of claim 16, wherein the IC includes temperature sensor circuitry having an output coupled to an input of the gain control circuitry, the temperature sensor circuitry configured to provide the digital temperature code.

18. The IC package of claim 16, wherein the calibration controller includes offset control circuitry and the calibration controller is configured to determine the calibration setting based on a temperature coefficient correction and based on operations of the offset control circuitry, the operations of the offset control circuitry including receiving a gain control code and adjusting an offset control code responsive to the gain control code.

19. The IC package of claim 16, wherein the calibration controller is configured to determine the calibration setting based on a piecewise linear function or a polynomial function.

20. The IC package of claim 16, wherein the calibration controller is configured to determine the calibration setting based on a room temperature value and a package resistor value at the room temperature value.
